(19) United States
(12) Patent Application Publication
(10) Pub. No.: US 2025/0359045 A1
(43) Pub. Date: Nov. 20, 2025

(54) U-SHAPED CHANNEL ACCESS TRANSISTORS AND METHODS FOR FORMING THE SAME

(71) Applicant: Taiwan Semiconductor Manufacturing Company Limited, Hsinchu (TW)

(72) Inventors: Yun-Feng Kao, New Taipei City (TW); Katherine H. Chiang, New Taipei City (TW)

(21) Appl. No.: 19/291,008

(22) Filed: Aug. 5, 2025

Related U.S. Application Data
(62) Division of application No. 17/665,654, filed on Feb. 7, 2022.
(60) Provisional application No. 63/281,337, filed on Nov. 19, 2021.

(51) Int. Cl. H10B 41/27; H10B 12/00; H10D 86/00

(52) U.S. Cl. CPC H10B 41/27; H10B 12/02; H10B 12/30; H10D 86/215

(57) ABSTRACT

A transistor (e.g., TFT) includes a source region and a drain region located within an insulating matrix layer, a U-shaped channel plate contacting sidewalls of the source region and the drain region, a U-shaped gate dielectric contacting inner sidewalls of the U-shaped semiconducting metal oxide plate, and a gate electrode contacting inner sidewalls of the U-shaped gate dielectric.

### RELATED APPLICATIONS

This application is a divisional application of U.S. application Ser. No. 17/665,654 entitled “U-Shaped Channel Access Transistors and Methods for Forming the Same,” filed on Feb. 7, 2022, which claims the benefit of priority from U.S. Provisional Application No. 63/281,337 entitled “Semiconductor Device Structure”, filed on Nov. 19, 2021, the entire contents of both of which are hereby incorporated by reference for all purposes.

### BACKGROUND

Thin film transistors (TFT) made of oxide semiconductors are an attractive option for BEOL integration since TFTs may be processed at low temperatures and thus, will not damage previously fabricated devices. For example, the fabrication conditions and techniques may not damage previously fabricated FEOL devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a vertical cross-sectional view of a first exemplary structure after formation of complementary metal-oxide-semiconductor (CMOS) transistors, first metal interconnect structures formed in lower-level dielectric material layers, and an isolation dielectric layer according to an embodiment of the present disclosure.

FIG. 2A is a top-down view of a portion of a memory array region of the first exemplary structure after formation of bottom gate lines according to the first embodiment of the present disclosure. FIG. 2B is a vertical cross-sectional view along the vertical plane B-B′ of the first exemplary structure of FIG. 2A. FIG. 2C is a vertical cross-sectional view along the vertical plane C-C′ of the first exemplary structure of FIG. 2A. FIG. 2D is a vertical cross-sectional view along the vertical plane D-D′ of the first exemplary structure of FIG. 2A.

FIG. 3A is a top-down view of a portion of a memory array region of the first exemplary structure after formation of a bottom gate dielectric layer and an insulating matrix layer according to the first embodiment of the present disclosure. FIG. 3B is a vertical cross-sectional view along the vertical plane B-B′ of the first exemplary structure of FIG. 3A. FIG. 3C is a vertical cross-sectional view along the vertical plane C-C′ of the first exemplary structure of FIG. 3A. FIG. 3D is a vertical cross-sectional view along the vertical plane D-D′ of the first exemplary structure of FIG. 3A.

FIG. 4A is a top-down view of a portion of a memory array region of the first exemplary structure after formation of source trenches and drain trenches according to the first embodiment of the present disclosure. FIG. 4B is a vertical cross-sectional view along the vertical plane B-B′ of the first exemplary structure of FIG. 4A. FIG. 4C is a vertical cross-sectional view along the vertical plane C-C′ of the first exemplary structure of FIG. 4A. FIG. 4D is a vertical cross-sectional view along the vertical plane D-D′ of the first exemplary structure of FIG. 4A.

FIG. 5A is a top-down view of a portion of a memory array region of the first exemplary structure after formation of source strips and drain strips according to the first embodiment of the present disclosure. FIG. 5B is a vertical cross-sectional view along the vertical plane B-B′ of the first exemplary structure of FIG. 5A. FIG. 5C is a vertical cross-sectional view along the vertical plane C-C′ of the first exemplary structure of FIG. 5A. FIG. 5D is a vertical cross-sectional view along the vertical plane D-D′ of the first exemplary structure of FIG. 5A.

FIG. 6A is a top-down view of a portion of a memory array region of the first exemplary structure after formation of channel cavities according to the first embodiment of the present disclosure. FIG. 6B is a vertical cross-sectional view along the vertical plane B-B′ of the first exemplary structure of FIG. 6A. FIG. 6C is a vertical cross-sectional view along the vertical plane C-C′ of the first exemplary structure of FIG. 6A. FIG. 6D is a vertical cross-sectional view along the vertical plane D-D′ of the first exemplary structure of FIG. 6A.

FIG. 7A is a top-down view of a portion of a memory array region of the first exemplary structure after formation of a channel material layer and a gate dielectric layer according to the first embodiment of the present disclosure. FIG. 7B is a vertical cross-sectional view along the vertical plane B-B′ of the first exemplary structure of FIG. 7A. FIG. 7C is a vertical cross-sectional view along the vertical plane C-C′ of the first exemplary structure of FIG. 7A. FIG. 7D is a vertical cross-sectional view along the vertical plane D-D′ of the first exemplary structure of FIG. 7A.

FIG. 8A is a top-down view of a portion of a memory array region of the first exemplary structure after formation of etch mask material portions according to the first embodiment of the present disclosure. FIG. 8B is a vertical cross-sectional view along the vertical plane B-B′ of the first exemplary structure of FIG. 8A. FIG. 8C is a vertical cross-sectional view along the vertical plane C-C′ of the first exemplary structure of FIG. 8A. FIG. 8D is a vertical cross-sectional view along the vertical plane D-D′ of the first exemplary structure of FIG. 8A.

FIG. 9A is a top-down view of a portion of a memory array region of the first exemplary structure after patterning the gate dielectric layer and the channel material layer into gate dielectric strips and channel material strips according to the first embodiment of the present disclosure. FIG. 9B is a vertical cross-sectional view along the vertical plane B-B′ of the first exemplary structure of FIG. 9A. FIG. 9C is a vertical cross-sectional view along the vertical plane C-C′ of the first exemplary structure of FIG. 9A. FIG. 9D is a vertical cross-sectional view along the vertical plane D-D′ of the first exemplary structure of FIG. 9A.

FIG. 10A is a top-down view of a portion of a memory array region of the first exemplary structure after formation of isolation trenches that divide the source strips, the drain strips, the gate dielectric strips, and the channel material strips into source regions, drain regions, U-shaped gate dielectrics, and U-shaped channel plates according to the first embodiment of the present disclosure. FIG. 10B is a vertical cross-sectional view along the vertical plane B-B′ of the first exemplary structure of FIG. 10A. FIG. 10C is a vertical cross-sectional view along the vertical plane C-C′ of the first exemplary structure of FIG. 10A. FIG. 10D is a vertical cross-sectional view along the vertical plane D-D′ of the first exemplary structure of FIG. 10A. FIG. 10E is a vertical cross-sectional view along the vertical plane E-E′ of the first exemplary structure of FIG. 10A. FIG. 10F is a vertical cross-sectional view along the vertical plane F-F′ of the first exemplary structure of FIG. 10A.

FIG. 11A is a top-down view of a portion of a memory array region of the first exemplary structure after formation of a dielectric isolation layer according to the first embodiment of the present disclosure. FIG. 11B is a vertical cross-sectional view along the vertical plane B-B′ of the first exemplary structure of FIG. 11A. FIG. 11C is a vertical cross-sectional view along the vertical plane C-C′ of the first exemplary structure of FIG. 11A. FIG. 11D is a vertical cross-sectional view along the vertical plane D-D′ of the first exemplary structure of FIG. 11A. FIG. 11E is a vertical cross-sectional view along the vertical plane E-E′ of the first exemplary structure of FIG. 11A. FIG. 11F is a vertical cross-sectional view along the vertical plane F-F′ of the first exemplary structure of FIG. 11A.

FIG. 12A is a top-down view of a portion of a memory array region of the first exemplary structure after formation of gate cavities according to the first embodiment of the present disclosure. FIG. 12B is a vertical cross-sectional view along the vertical plane B-B′ of the first exemplary structure of FIG. 12A. FIG. 12C is a vertical cross-sectional view along the vertical plane C-C′ of the first exemplary structure of FIG. 12A. FIG. 12D is a vertical cross-sectional view along the vertical plane D-D′ of the first exemplary structure of FIG. 12A. FIG. 12E is a vertical cross-sectional view along the vertical plane E-E′ of the first exemplary structure of FIG. 12A. FIG. 12F is a vertical cross-sectional view along the vertical plane F-F′ of the first exemplary structure of FIG. 12A.

FIG. 13A is a top-down view of a portion of a memory array region of the first exemplary structure after formation of gate electrodes according to the first embodiment of the present disclosure. FIG. 13B is a vertical cross-sectional view along the vertical plane B-B′ of the first exemplary structure of FIG. 13A. FIG. 13C is a vertical cross-sectional view along the vertical plane C-C′ of the first exemplary structure of FIG. 13A. FIG. 13D is a vertical cross-sectional view along the vertical plane D-D′ of the first exemplary structure of FIG. 13A. FIG. 13E is a vertical cross-sectional view along the vertical plane E-E′ of the first exemplary structure of FIG. 13A. FIG. 13F is a vertical cross-sectional view along the vertical plane F-F′ of the first exemplary structure of FIG. 13A.

FIG. 14A is a top-down view of a portion of a memory array region of the first exemplary structure after formation of contact via structures, source-side lines, and bit lines according to the first embodiment of the present disclosure. FIG. 14B is a vertical cross-sectional view along the vertical plane B-B′ of the first exemplary structure of FIG. 14A. FIG. 14C is a vertical cross-sectional view along the vertical plane C-C′ of the first exemplary structure of FIG. 14A. FIG. 14D is a vertical cross-sectional view along the vertical plane D-D′ of the first exemplary structure of FIG. 14A. FIG. 14E is a vertical cross-sectional view along the vertical plane E-E′ of the first exemplary structure of FIG. 14A. FIG. 14F is a vertical cross-sectional view along the vertical plane F-F′ of the first exemplary structure of FIG. 14A.

FIG. 15A is a top-down view of a portion of a memory array region of the first exemplary structure after formation of source-connection via structures and source-connection pads according to the first embodiment of the present disclosure. FIG. 15B is a vertical cross-sectional view along the vertical plane B-B′ of the first exemplary structure of FIG. 15A. FIG. 15C is a vertical cross-sectional view along the vertical plane C-C′ of the first exemplary structure of FIG. 15A. FIG. 15D is a vertical cross-sectional view along the vertical plane D-D′ of the first exemplary structure of FIG. 15A. FIG. 15E is a vertical cross-sectional view along the vertical plane E-E′ of the first exemplary structure of FIG. 15A. FIG. 15F is a vertical cross-sectional view along the vertical plane F-F′ of the first exemplary structure of FIG. 15A.

FIG. 16A is a top-down view of a portion of a memory array region of the first exemplary structure after formation of capacitor structures according to the first embodiment of the present disclosure. FIG. 16B is a vertical cross-sectional view along the vertical plane B-B′ of the first exemplary structure of FIG. 16A. FIG. 16C is a vertical cross-sectional view along the vertical plane C-C′ of the first exemplary structure of FIG. 16A. FIG. 16D is a vertical cross-sectional view along the vertical plane D-D′ of the first exemplary structure of FIG. 16A. FIG. 16E is a vertical cross-sectional view along the vertical plane E-E′ of the first exemplary structure of FIG. 16A. FIG. 16F is a vertical cross-sectional view along the vertical plane F-F′ of the first exemplary structure of FIG. 16A.

FIG. 17A is a top-down view of a portion of a memory array region of a second exemplary structure after formation of gate electrodes according to a second embodiment of the present disclosure. FIG. 17B is a vertical cross-sectional view along the vertical plane B-B′ of the second exemplary structure of FIG. 17A. FIG. 17C is a vertical cross-sectional view along the vertical plane C-C′ of the second exemplary structure of FIG. 17A. FIG. 17D is a vertical cross-sectional view along the vertical plane D-D′ of the second exemplary structure of FIG. 17A. FIG. 17E is a vertical cross-sectional view along the vertical plane E-E′ of the second exemplary structure of FIG. 17A. FIG. 17F is a vertical cross-sectional view along the vertical plane F-F′ of the second exemplary structure of FIG. 17A.

FIG. 18A is a top-down view of a portion of a memory array region of the second exemplary structure after formation of capacitor structures according to the second embodiment of the present disclosure. FIG. 18B is a vertical cross-sectional view along the vertical plane B-B′ of the second exemplary structure of FIG. 18A. FIG. 18C is a vertical cross-sectional view along the vertical plane C-C′ of the second exemplary structure of FIG. 18A. FIG. 18D is a vertical cross-sectional view along the vertical plane D-D′ of the second exemplary structure of FIG. 18A. FIG. 18E is a vertical cross-sectional view along the vertical plane E-E′ of the second exemplary structure of FIG. 18A. FIG. 18F is a vertical cross-sectional view along the vertical plane F-F′ of the second exemplary structure of FIG. 18A.

FIG. 19A is a top-down view of a portion of a memory array region of a third exemplary structure after formation of capacitor structures according to a third embodiment of the present disclosure. FIG. 19B is a vertical cross-sectional view along the vertical plane B-B′ of the third exemplary structure of FIG. 19A. FIG. 19C is a vertical cross-sectional view along the vertical plane C-C′ of the third exemplary structure of FIG. 19A. FIG. 19D is a vertical cross-sectional view along the vertical plane D-D′ of the third exemplary structure of FIG. 19A. FIG. 19E is a vertical cross-sectional view along the vertical plane E-E′ of the third exemplary structure of FIG. 19A. FIG. 19F is a vertical cross-sectional view along the vertical plane F-F′ of the third exemplary structure of FIG. 19A.

FIG. 20A is a top-down view of a portion of a memory array region of a first alternative embodiment of the third exemplary structure after formation of capacitor structures according to the third embodiment of the present disclosure. FIG. 20B is a vertical cross-sectional view along the vertical plane B-B′ of the third exemplary structure of FIG. 20A. FIG. 20C is a vertical cross-sectional view along the vertical plane C-C′ of the third exemplary structure of FIG. 20A. FIG. 20D is a vertical cross-sectional view along the vertical plane D-D′ of the third exemplary structure of FIG. 20A. FIG. 20E is a vertical cross-sectional view along the vertical plane E-E′ of the third exemplary structure of FIG. 20A. FIG. 20F is a vertical cross-sectional view along the vertical plane F-F′ of the third exemplary structure of FIG. 20A.

FIG. 21A is a top-down view of a portion of a memory array region of a second alternative embodiment of the third exemplary structure after formation of capacitor structures according to the third embodiment of the present disclosure. FIG. 21B is a vertical cross-sectional view along the vertical plane B-B′ of the third exemplary structure of FIG. 21A. FIG. 21C is a vertical cross-sectional view along the vertical plane C-C′ of the third exemplary structure of FIG. 21A. FIG. 21D is a vertical cross-sectional view along the vertical plane D-D′ of the third exemplary structure of FIG. 21A. FIG. 21E is a vertical cross-sectional view along the vertical plane E-E′ of the third exemplary structure of FIG. 21A. FIG. 21F is a vertical cross-sectional view along the vertical plane F-F′ of the third exemplary structure of FIG. 21A.

FIG. 22A is a top-down view of a portion of a memory array region of a fourth exemplary structure after formation of gate dielectric strips and channel material strips according to a fourth embodiment of the present disclosure. FIG. 22B is a vertical cross-sectional view along the vertical plane B-B′ of the fourth exemplary structure of FIG. 22A. FIG. 22C is a vertical cross-sectional view along the vertical plane C-C′ of the fourth exemplary structure of FIG. 22A. FIG. 22D is a vertical cross-sectional view along the vertical plane D-D′ of the fourth exemplary structure of FIG. 22A.

FIG. 23A is a top-down view of a portion of a memory array region of the fourth exemplary structure after formation of capacitor structures according to the fourth embodiment of the present disclosure. FIG. 23B is a vertical cross-sectional view along the vertical plane B-B′ of the fourth exemplary structure of FIG. 23A. FIG. 23C is a vertical cross-sectional view along the vertical plane C-C′ of the fourth exemplary structure of FIG. 23A. FIG. 23D is a vertical cross-sectional view along the vertical plane D-D′ of the fourth exemplary structure of FIG. 23A. FIG. 23E is a vertical cross-sectional view along the vertical plane E-E′ of the fourth exemplary structure of FIG. 23A. FIG. 23F is a vertical cross-sectional view along the vertical plane F-F′ of the fourth exemplary structure of FIG. 23A.

FIG. 24A is a top-down view of a portion of a memory array region of a fifth exemplary structure after formation of capacitor structures according to the fifth embodiment of the present disclosure. FIG. 24B is a vertical cross-sectional view along the vertical plane B-B′ of the fifth exemplary structure of FIG. 24A. FIG. 24C is a vertical cross-sectional view along the vertical plane C-C′ of the fifth exemplary structure of FIG. 24A. FIG. 24D is a vertical cross-sectional view along the vertical plane D-D′ of the fifth exemplary structure of FIG. 24A. FIG. 24E is a vertical cross-sectional view along the vertical plane E-E′ of the fifth exemplary structure of FIG. 24A. FIG. 24F is a vertical cross-sectional view along the vertical plane F-F′ of the fifth exemplary structure of FIG. 24A.

FIG. 25 is a vertical cross-sectional view of an exemplary structure after formation of additional upper-level dielectric material layers and additional upper-level metal interconnect structures according to an embodiment of the present disclosure.

FIG. 26 is a flowchart that illustrates the general processing steps for manufacturing the semiconductor device of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Elements with the same reference numerals refer to the same element, and are presumed to have the same material composition and the same thickness range unless expressly indicated otherwise.

Generally, the structures and methods of the present disclosure may be used to form a transistor (e.g., a thin-film transistor, TFT) including a U-shaped semiconductor channel that may include a U-shaped channel plate that is self-aligned to a source region and a drain region. A gate electrode may be spaced from the U-shaped channel plate by a U-shaped gate dielectric having a uniform thickness throughout. Thus, the gate electrode may be self-aligned to the U-shaped semiconductor channel and also to the source region and to the drain region. The self-alignment of the gate electrode to the source region, the drain region, and the U-shaped semiconductor channel may mitigate gate overlay variation issues and reduce performance variations in the transistor. Various embodiments of the present disclosure are now described with reference to accompanying drawings.

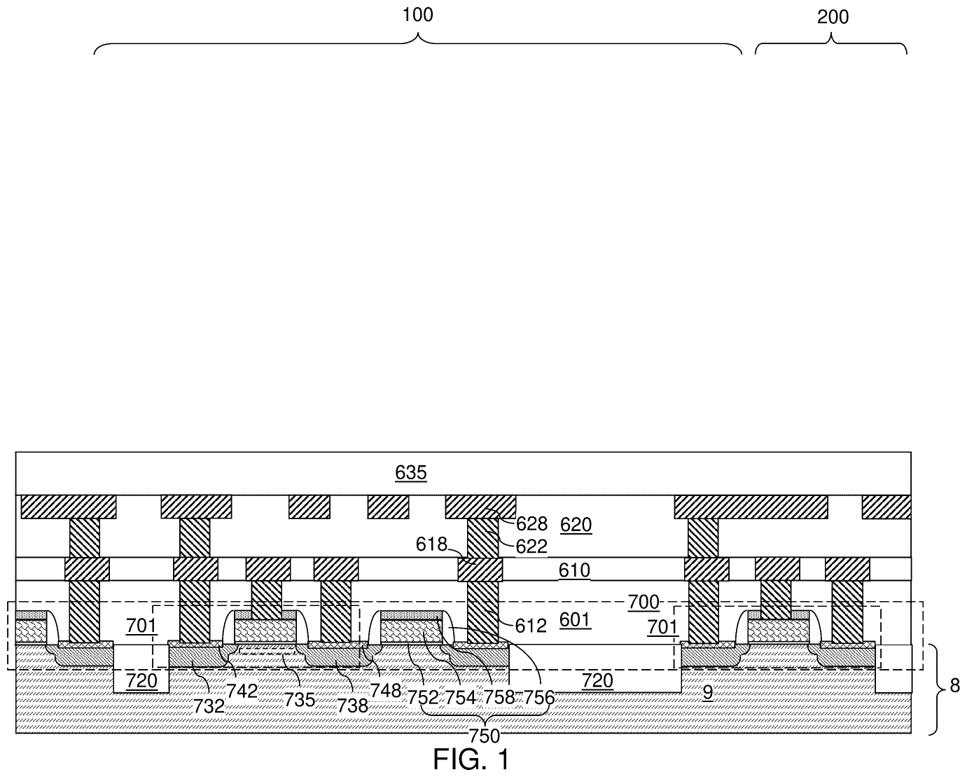

Referring to FIG. 1, a first exemplary structure according to a first embodiment of the present disclosure is illustrated. The first exemplary structure includes a substrate 8, which may be a semiconductor substrate such as a commercially available silicon substrate. The substrate 8 may include a semiconductor material layer 9 at least at an upper portion thereof. The semiconductor material layer 9 may be a surface portion of a bulk semiconductor substrate, or may be a top semiconductor layer of a semiconductor-on-insulator (SOI) substrate. In one embodiment, the semiconductor material layer 9 includes a single crystalline semiconductor material such as single crystalline silicon. In one embodiment, the substrate 8 may include a single crystalline silicon substrate including a single crystalline silicon material.

Shallow trench isolation structures 720 including a dielectric material such as silicon oxide may be formed in an upper portion of the semiconductor material layer 9. Suitable doped semiconductor wells, such as p-type wells and n-type wells, may be formed within each area that is laterally enclosed by a portion of the shallow trench isolation structures 720. Field effect transistors 701 may be formed over the top surface of the semiconductor material layer 9. For example, each field effect transistor 701 may include a source region 732, a drain region 738, a semiconductor channel 735 that includes a surface portion of the substrate 8 extending between the source region 732 and the drain region 738, and a gate structure 750. The semiconductor channel 735 may include a single crystalline semiconductor material. Each gate structure 750 may include a gate dielectric layer 752, a gate electrode 754, a gate cap dielectric 758, and a dielectric gate spacer 756. A source-side metal-semiconductor alloy region 742 may be formed on each source region 732, and a drain-side metal-semiconductor alloy region 748 may be formed on each drain region 738.

The first exemplary structure may include a memory array region 100 in which an array of ferroelectric memory cells may be subsequently formed. The first exemplary structure may further include a peripheral region 200 in which metal wiring for the array of ferroelectric memory devices is provided. Generally, the field effect transistors 701 in the CMOS circuitry 700 may be electrically connected to an electrode of a respective ferroelectric memory cell by a respective set of metal interconnect structures.

Devices (such as field effect transistors 701) in the peripheral region 200 may provide functions that operate the array of memory cells (e.g., ferroelectric memory cells) to be subsequently formed. Specifically, devices in the peripheral region may be configured to control the programming operation, the erase operation, and the sensing (read) operation of the array of memory cells (e.g., ferroelectric memory cells). For example, the devices in the peripheral region may include a sensing circuitry and/or a programming circuitry. The devices formed on the top surface of the semiconductor material layer 9 may include complementary metal-oxide-semiconductor (CMOS) transistors and optionally additional semiconductor devices (such as resistors, diodes, capacitors, etc.), and are collectively referred to as CMOS circuitry 700.

One or more of the field effect transistors 701 in the CMOS circuitry 700 may include a semiconductor channel 735 that may contain a portion of the semiconductor material layer 9 in the substrate 8. In embodiments in which the semiconductor material layer 9 includes a single crystalline semiconductor material such as single crystalline silicon, the semiconductor channel 735 of each field effect transistor 701 in the CMOS circuitry 700 may include a single crystalline semiconductor channel such as a single crystalline silicon channel. In one embodiment, a plurality of field effect transistors 701 in the CMOS circuitry 700 may include a respective node that is subsequently electrically connected to a node of a respective memory cell (e.g., a node of a respective ferroelectric memory cell) to be subsequently formed. For example, a plurality of field effect transistors 701 in the CMOS circuitry 700 may include a respective source region 732 or a respective drain region 738 that is subsequently electrically connected to a node of a respective memory cell to be subsequently formed.

In one embodiment, the CMOS circuitry 700 may include a programming control circuit configured to control gate voltages of a set of field effect transistors 701 that are used for programming a respective ferroelectric memory cell and to control gate voltages of transistors (e.g., TFTs) to be subsequently formed. In this embodiment, the programming control circuit may be configured to provide a first programming pulse that programs a respective dielectric material layer in a selected memory cell such as a ferroelectric dielectric material in a selected ferroelectric memory cell into a first polarization state in which electrical polarization in the ferroelectric dielectric material layer points toward a first electrode of the selected ferroelectric memory cell, and to provide a second programming pulse that programs the ferroelectric dielectric material layer in the selected ferroelectric memory cell into a second polarization state in which the electrical polarization in the ferroelectric dielectric material layer points toward a second electrode of the selected ferroelectric memory cell.

In one embodiment, the substrate 8 may include a single crystalline silicon substrate, and the field effect transistors 701 may include a respective portion of the single crystalline silicon substrate as a semiconducting channel. As used herein, a “semiconducting” element refers to an element having electrical conductivity in the range from 1.0×10⁻⁶ S/cm to 1.0×10⁵ S/cm. As used herein, a “semiconductor material” refers to a material having electrical conductivity in the range from 1.0×10⁻⁶ S/cm to 1.0×10⁵ S/cm in the absence of electrical dopants therein, and is capable of producing a doped material having electrical conductivity in a range from 1.0 S/cm to 1.0×10⁵ S/cm upon suitable doping with an electrical dopant.

According to an aspect of the present disclosure, the field effect transistors 701 may be subsequently electrically connected to drain regions and gate electrodes of access transistors including semiconducting metal oxide plates to be formed above the field effect transistors 701. In one embodiment, a subset of the field effect transistors 701 may be subsequently electrically connected to at least one of the drain regions and the gate electrodes. For example, the field effect transistors 701 may comprise first word line drivers configured to apply a first gate voltage to first word lines through a first subset of lower-level metal interconnect structures to be subsequently formed, and second word line drivers configured to apply a second gate voltage to second word lines through a second subset of the lower-level metal interconnect structures. Further, the field effect transistors 701 may comprise bit line drivers configured to apply a bit line bias voltage to bit lines to be subsequently formed, and sense amplifiers configured to detect electrical current that flows through the bit lines during a read operation.

Various metal interconnect structures formed within dielectric material layers may be subsequently formed over the substrate 8 and the semiconductor devices thereupon (such as field effect transistors 701). In an illustrative example, the dielectric material layers may include, for example, a first dielectric material layer 601 that may be a layer that surrounds the contact structure connected to the source and drains (sometimes referred to as a contact-level dielectric material layer 601), a first interconnect-level dielectric material layer 610, and a second interconnect-level dielectric material layer 620. The metal interconnect structures may include device contact via structures 612 formed in the first dielectric material layer 601 and contacting a respective component of the CMOS circuitry 700, first metal line structures 618 formed in the first interconnect-level dielectric material layer 610, first metal via structures 622 formed in a lower portion of the second interconnect-level dielectric material layer 620, and second metal line structures 628 formed in an upper portion of the second interconnect-level dielectric material layer 620.

Each of the dielectric material layers (601, 610, 620) may include a dielectric material such as undoped silicate glass, a doped silicate glass, organosilicate glass, amorphous fluorinated carbon, porous variants thereof, or combinations thereof. Each of the metal interconnect structures (612, 618, 622, 628) may include at least one conductive material, which may be a combination of a metallic liner (such as a metallic nitride or a metallic carbide) and a metallic fill material. Each metallic liner may include TiN, TaN, WN, TiC, TaC, and WC, and each metallic fill material portion may include W, Cu, Al, Co, Ru, Mo, Ta, Ti, alloys thereof, and/or combinations thereof. Other suitable metallic liner and metallic fill materials within the contemplated scope of disclosure may also be used. In one embodiment, the first metal via structures 622 and the second metal line structures 628 may be formed as integrated line and via structures by a dual damascene process. The dielectric material layers (601, 610, 620) are herein referred to as lower-level dielectric material layers. The metal interconnect structures (612, 618, 622, 628) located within in the lower-level dielectric material layers are herein referred to as lower-level metal interconnect structures.

While the present disclosure is described using an embodiment in which an array of memory cells may be formed over the second line-and-via-level dielectric material layer 620, embodiments are expressly contemplated herein in which the array of memory cells may be formed at a different metal interconnect level.

An array of transistors (e.g., TFTs) and an array of memory cells (e.g., ferroelectric memory cells) may be subsequently deposited over the dielectric material layers (601, 610, 620) that have formed therein the metal interconnect structures (612, 618, 622, 628). The set of all dielectric material layer that are formed prior to formation of an array of transistors (e.g., TFTs) or an array of memory cells is collectively referred to as lower-level dielectric material layers (601, 610, 620). The set of all metal interconnect structures that is located within the lower-level dielectric material layers (601, 610, 620) is herein referred to as first metal interconnect structures (612, 618, 622, 628). Generally, first metal interconnect structures (612, 618, 622, 628) and at least one lower-level dielectric material layer (601, 610, 620) may be formed over the semiconductor material layer 9 that is located in the substrate 8.

According to an aspect of the present disclosure, transistors (e.g., TFTs) may be subsequently formed in a metal interconnect level that overlies that metal interconnect levels that contain the lower-level dielectric material layers (601, 610, 620) and the first metal interconnect structures (612, 618, 622, 628). In one embodiment, a planar dielectric material layer having a uniform thickness may be formed over the lower-level dielectric material layers (601, 610, 620). The planar dielectric material layer is herein referred to as an insulating material layer 635. The insulating material layer 635 includes a dielectric material such as undoped silicate glass, a doped silicate glass, organosilicate glass, or a porous dielectric material, and may be deposited by chemical vapor deposition. The thickness of the insulating material layer 635 may be in a range from 20 nm to 300 nm, although lesser and greater thicknesses may also be used.

Generally, interconnect-level dielectric layers (such as the lower-level dielectric material layer (601, 610, 620)) containing therein the metal interconnect structures (such as the first metal interconnect structures (612, 618, 622, 628)) may be formed over semiconductor devices. The insulating material layer 635 may be formed over the interconnect-level dielectric layers.

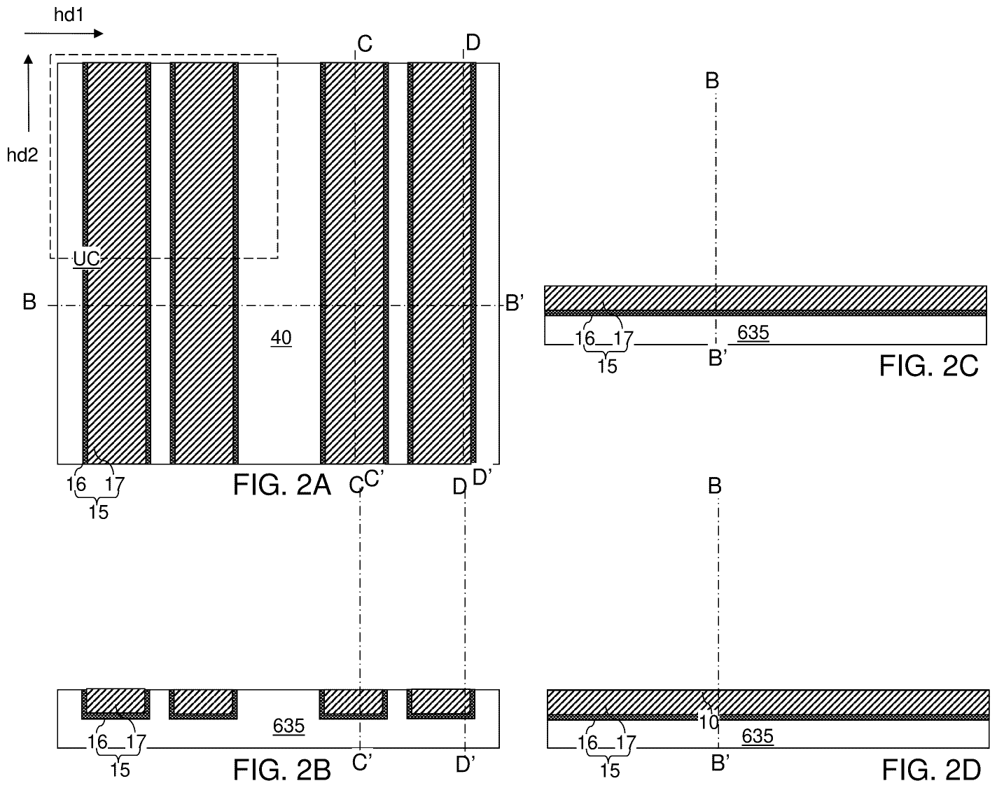

Referring to FIGS. 2A-2D, a portion of a memory array region of the first exemplary structure is illustrated, which corresponds to the area of four unit cells UC of a two-dimensional array of dynamic random access memory cells to be subsequently formed. Instances of the unit cell UC may be repeated along the first horizontal direction hd1 and along the second horizontal direction hd2. Each unit cell UC may have an area for forming a pair of dynamic random access memory cells, each of which includes a series connection of a respective access transistor and a respective capacitor structure.

A photoresist layer (not shown) may be applied over a top surface of the insulating material layer 635, and may be lithographically patterned to form line-shaped openings that may be laterally spaced apart along a first horizontal direction hd1 and laterally extend along a second horizontal direction hd2 that is perpendicular to the first horizontal direction hd1. An anisotropic etch process may be performed to transfer the pattern of the line-shaped openings in the photoresist layer into an upper portion of the insulating material layer 635. Line trenches may be formed in an upper portion of the insulating material layer 635. The line trenches are herein referred to as bottom gate trenches. Each of the line trenches may laterally extend along the second horizontal direction through a respective column of unit cells UC. The line trenches may have a uniform width along the first horizontal direction hd1, and neighboring pairs of line trenches may be laterally spaced apart along the first horizontal direction with a respective uniform spacing.

In one embodiment, the width of each of the bottom gate trenches along the first horizontal direction hd1 may be in a range from 20 nm to 300 nm, although lesser and greater widths may also be used. The depth of each of the bottom gate trenches may be in a range from 20 nm to 150 nm, although lesser and greater depths may also be used. The width-to-height ratio of each bottom gate trench may be in a range from 0.5 to 4, such as from 1 to 2, although lesser and greater ratios may also be used. The photoresist layer may be subsequently removed, for example, by ashing.

At least one conductive material may be deposited in the bottom gate trenches. The at least one conductive material may include, for example, a metallic barrier liner material (such as TiN, TaN, and/or WN) and a metallic fill material (such as Cu, W, Mo, Co, Ru, etc.). Other suitable metallic liner and metallic fill materials within the contemplated scope of disclosure may also be used. Excess portions of the at least one conductive material may be removed from above the horizontal plane including the top surface of the insulating material layer 635 by a planarization process, which may include a chemical mechanical polishing (CMP) process and/or a recess etch process. Bottom gate electrodes 15 (which are bottom gate lines) may be formed in the bottom gate trenches. Each unit cell area UC may have an areal overlap with respective portions of a pair of bottom gate electrodes 15. Each of the bottom gate electrodes 15 may include a lower metallic barrier liner 16 and a lower metallic gate material portion 17. Each lower metallic barrier liner 16 may include a remaining portion of the metallic barrier liner material. Each lower metallic gate material portion 17 may include a remaining portion of the metallic fill material. Generally, at least one conductive material may be deposited and planarized in the first line trenches and the second line trenches.

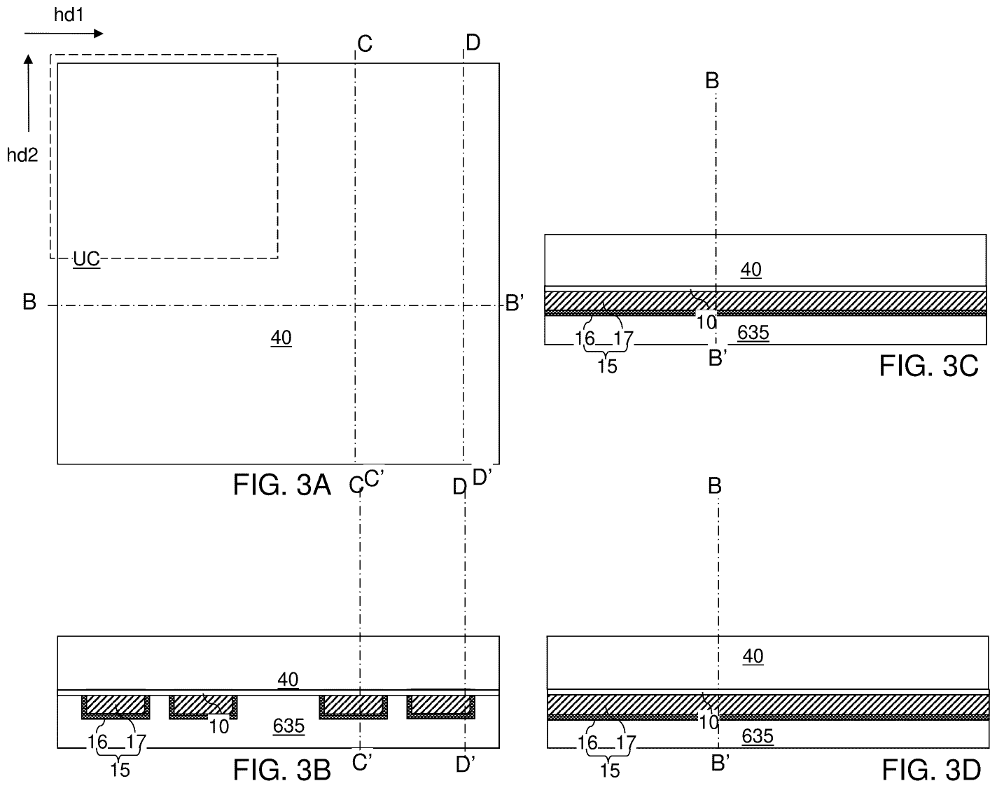

Referring to FIGS. 3A-3D, a bottom gate dielectric layer 10 and an insulating matrix layer 40 may be sequentially deposited over the insulating material layer 635 and the bottom gate electrodes 15.

The bottom gate dielectric layer 10 may be formed over the insulating material layer 635 and the bottom gate electrodes 15 by deposition of at least one gate dielectric material. The gate dielectric material may include, but is not limited to, silicon oxide, silicon oxynitride, a dielectric metal oxide (such as aluminum oxide, hafnium oxide, yttrium oxide, lanthanum oxide, etc.), or a stack thereof. Other suitable dielectric materials are within the contemplated scope of disclosure. The gate dielectric material may be deposited by atomic layer deposition or chemical vapor deposition. The thickness of the bottom gate dielectric layer 10 may be in a range from 1 nm to 12 nm, such as from 2 nm to 6 nm, although lesser and greater thicknesses may also be used.

The insulating matrix layer 40 may include a dielectric material that may be subsequently patterned by anisotropic etching. For example, the insulating matrix layer 40 may include undoped silicate glass or a doped silicate glass (such as phosphosilicate glass), and may have a thickness in a range from 30 nm to 600 nm, such as from 60 nm to 300 nm, although lesser and greater thicknesses may also be used.

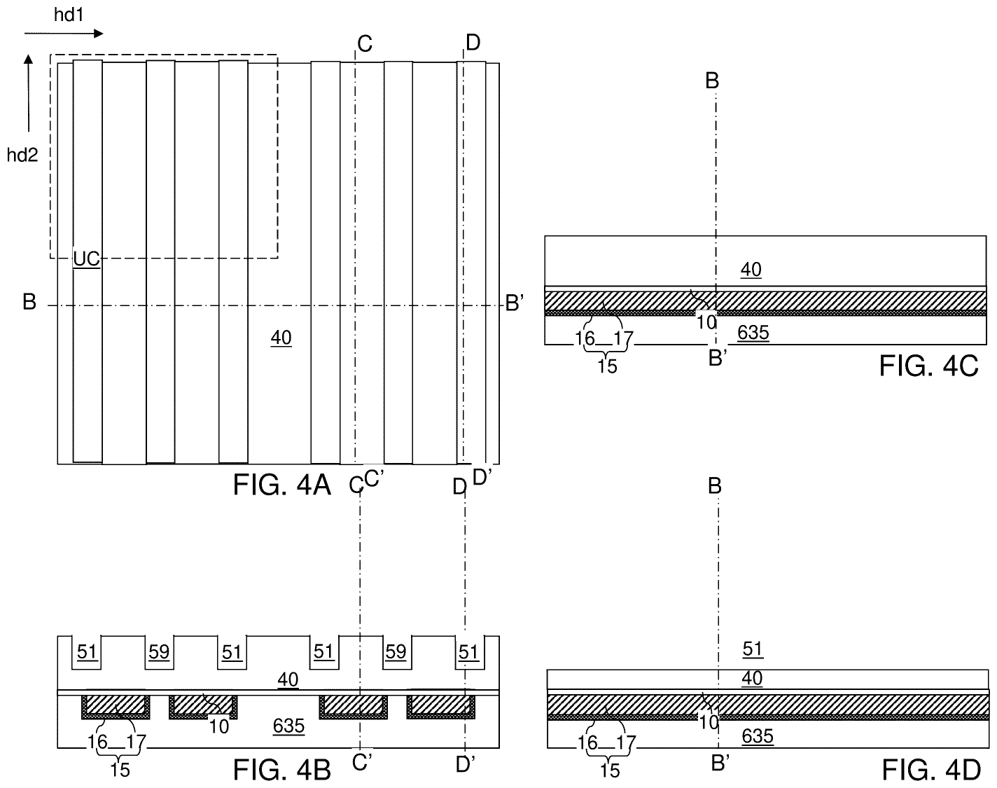

Referring to FIGS. 4A-4D, a photoresist layer (not shown) may be applied over the insulating matrix layer 40, and may be lithographically patterned to form line trenches laterally extending along the second horizontal direction and laterally spaced apart along the first horizontal direction. The pattern of the line trenches in the photoresist layer may be transferred through the insulating matrix layer 40 to form source trenches 51 and drain trenches 59.

In one embodiment, a pair of source trenches 51 and a drain trench 59 may laterally extend along the second horizontal direction hd2 within the area of each unit cell UC. The drain trench 59 may be located between the pair of source trenches 51. Each of the source trenches 51 and the drain trenches 59 may have a respective uniform width along the first horizontal direction hd1. The width of each of the source trenches 51 and the drain trenches 59 along the first horizontal direction hd1 may be in a range from 10 nm to 200 nm, although lesser and greater widths may also be used. The depth of the source trenches 51 and the drain trenches 59 may be less than the thickness of the insulating matrix layer 40. The depth of the source trenches 51 and the drain trenches 59 may be in a range from 20 nm to 400 nm, such as from 40 nm to 200 nm, although lesser and greater thicknesses may also be used.

The spacing between each drain trench 59 and a respective neighboring source trench 51 defines a horizontal channel length for the transistors that are subsequently formed. As such, the spacing between each drain trench 59 and a respective neighboring source trench 51 may be uniform, and may be in a range from 10 nm to 300 nm, such as from 20 nm to 150 nm, although lesser and greater spacings may also be used. The photoresist layer may be subsequently removed, for example, by ashing.

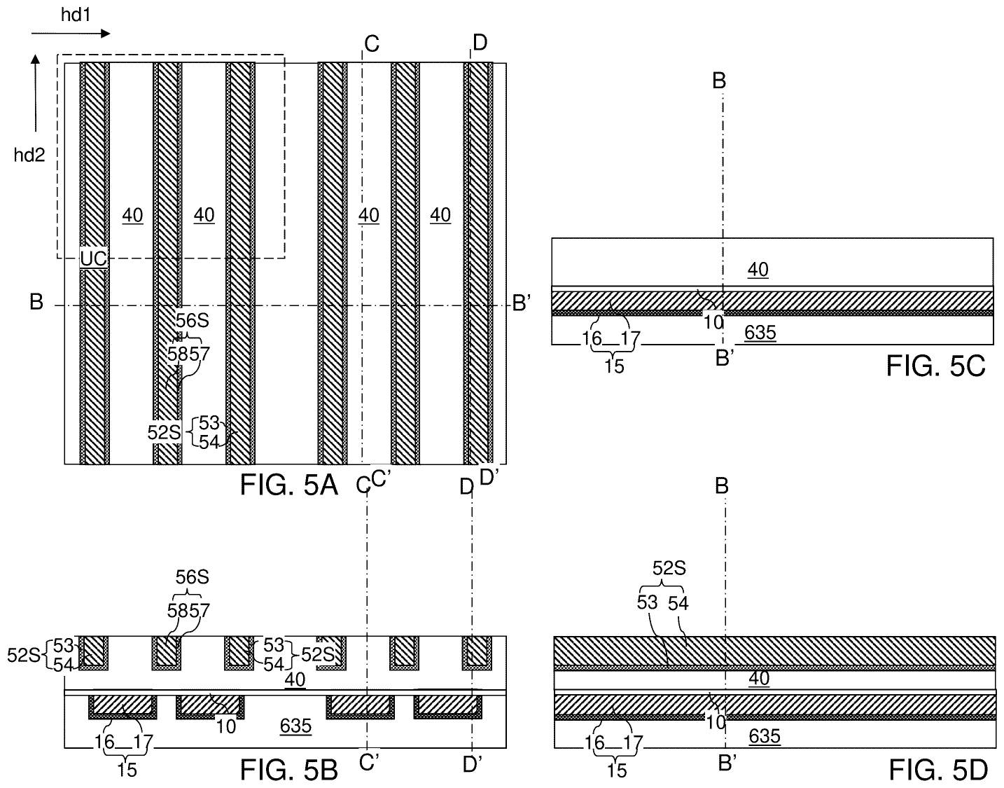

Referring to FIGS. 5A-5D, at least one conductive material may be deposited in the source and drain trenches (51, 59) and over the insulating matrix layer 40. The at least one conductive material may include a metallic liner material and a metallic fill material. The metallic liner material may include a conductive metallic nitride or a conductive metallic carbide such as TiN, TaN, WN, TiC, TaC, and/or WC. The metallic fill material may include W, Cu, Al, Co, Ru, Mo, Ta, Ti, alloys thereof, and/or combinations thereof. Other suitable materials within the contemplated scope of disclosure may also be used.

Excess portions of the at least one conductive material may be removed from above the horizontal plane including the top surface of the insulating matrix layer 40 by a planarization process, which may use a CMP process and/or a recess etch process. Other suitable planarization processes may be used. Each remaining portion of the at least one conductive material filling a source trench 51 constitutes a source strip 52S. Each remaining portion of the at least one conductive material filling a drain trench 59 constitutes a drain strip 56S.

In one embodiment, each source strip 52S may include a source metallic liner 53 that is a remaining portion of the metallic liner material, and a source metallic fill material portion 54 that is a remaining portion of the metallic fill material. Each drain strip 56S may include a drain metallic liner 57 that is a remaining portion of the metallic liner material, and a drain metallic fill material portion 58 that is a remaining portion of the metallic fill material. Generally, source strips 52S and drain strips 56S may be formed in an upper portion of the insulating matrix layer 40. Each neighboring pair of a source strip 52S and a drain strip 56S may be laterally spaced apart along the first horizontal direction hd1.

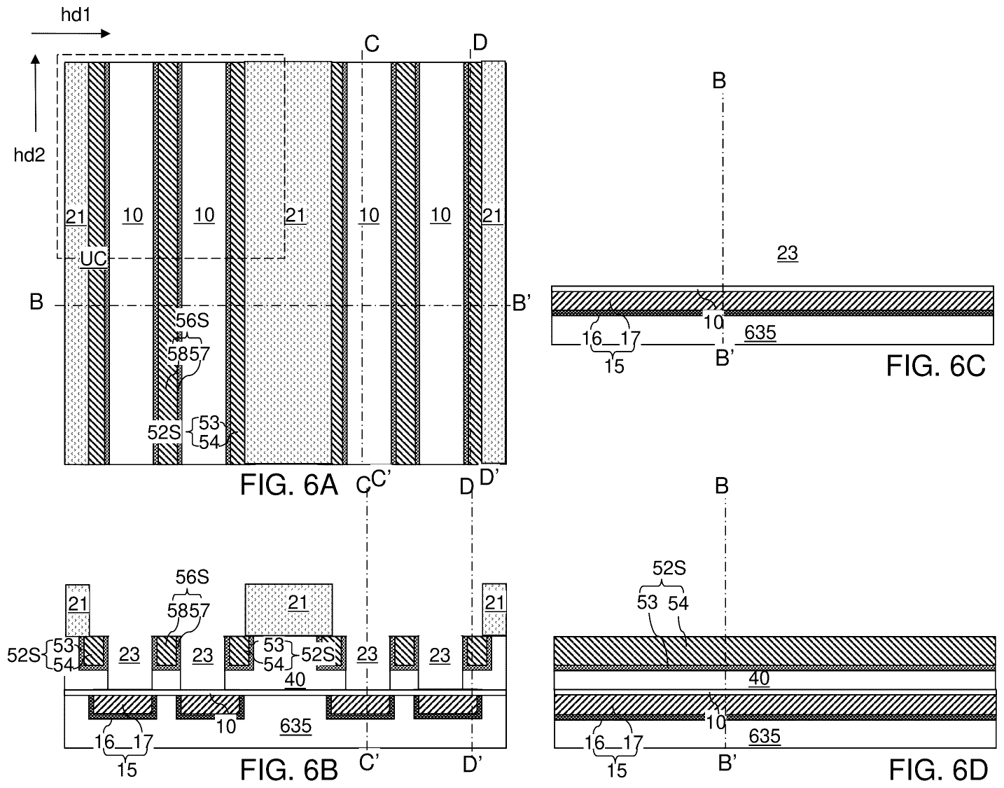

Referring to FIGS. 6A-6D, a photoresist layer 21 may be applied over the insulating matrix layer 40, the source strips 52S, and the drain strips 56S, and may be lithographically patterned to form line-shaped openings that overlie the portions of the insulating matrix layer 40 between neighboring pairs of a respective source strip 52S and a respective drain strip 56S.

An anisotropic etch process may be performed to etch unmasked portions of the insulating matrix layer 40 selective to the materials of the source strips 52S and the drain strips 56S, and selective to the material of the bottom gate dielectric layer 10. Thus, the combination of the patterned photoresist layer 21, the source strips 52S, and the drain strips 56S may be used as an etch mask for the anisotropic etch process. Channel cavities 23 may be formed in volumes from which the material of the insulating matrix layer 40 is removed. A segment of the top surface of the bottom gate dielectric layer 10 may be physically exposed at the bottom of each channel cavity 23. Each channel cavity 23 may have a rectangular vertical cross-sectional shape within each vertical plane laterally extending along the first horizontal direction hd1 and extending through the regions of the unit cells UC. Each channel cavity 23 may be laterally bounded by a straight sidewall of a source strip 52S and a straight sidewall of a drain strip 56S, and may be vertically bounded by the top surface of the bottom gate dielectric layer 10. The photoresist layer 21 may be subsequently removed, for example, by ashing.

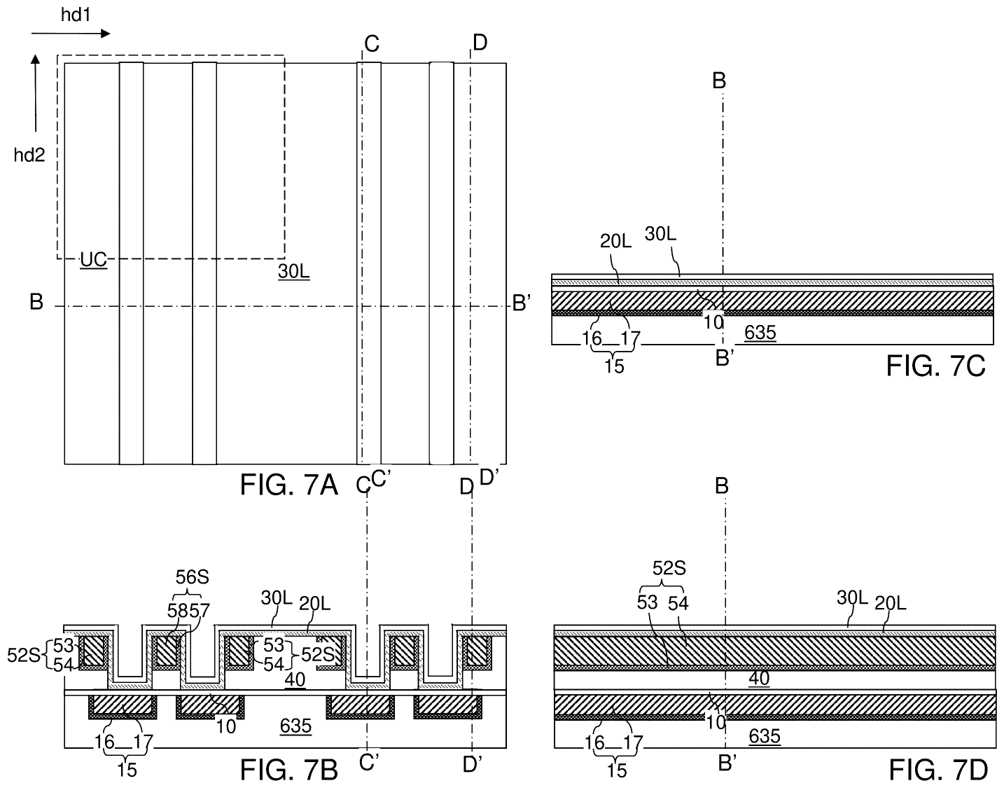

Referring to FIGS. 7A-7D, a layer stack of a channel material layer 20L and a gate dielectric layer 30L may be deposited over physically exposed surfaces of the channel cavities 23. The channel material layer 20L may be deposited directly on physically exposed top surface segments of the bottom gate dielectric layer 10, sidewalls of the source strips 52S and the drain strips 56S, and top surfaces of the source strips 52S and the drain strips 56S. In one embodiment, the channel material layer 20L comprises a semiconducting material that provides electrical conductivity in a range from 1.0 S/m to 1.0×10⁵ S/m upon suitable doping with electrical dopants (which may be p-type dopants or n-type dopants). Exemplary semiconducting materials that may be used for the channel material layer 20L include, but are not limited to, indium gallium zinc oxide (IGZO), indium tungsten oxide, indium zinc oxide, indium tin oxide, gallium oxide, indium oxide, doped zinc oxide, doped indium oxide, doped cadmium oxide, and various other doped variants derived therefrom. Alternatively, amorphous silicon, polysilicon, or a silicon-germanium alloy may be used for the channel material layer 20L. Other suitable semiconducting materials are within the contemplated scope of disclosure. In one embodiment, the semiconducting material of the channel material layer 20L may include indium gallium zinc oxide.

The channel material layer 20L may include a polycrystalline semiconducting material, or an amorphous semiconducting material that may be subsequently annealed into a polycrystalline semiconducting material having a greater average grain size. The channel material layer 20L may be deposited by a first conformal deposition process such as a chemical vapor deposition process, although other suitable deposition processes such as a physical vapor deposition may be used. The thickness of the channel material layer 20L (as measured at a horizontally-extending portion overlying the bottom gate dielectric layer 10) may be in a range from 1 nm to 100 nm, such as from 2 nm to 30 nm and/or from 4 nm to 15 nm, although lesser and greater thicknesses may also be used.

The gate dielectric layer 30L may be formed over the channel material layer 20L by deposition of at least one gate dielectric material. The gate dielectric material may include, but is not limited to, silicon oxide, silicon oxynitride, a dielectric metal oxide (such as aluminum oxide, hafnium oxide, yttrium oxide, lanthanum oxide, etc.), or a stack thereof. Other suitable dielectric materials are within the contemplated scope of disclosure. The gate dielectric material may be deposited by a second conformal deposition process such as an atomic layer deposition process or a chemical vapor deposition process, although other suitable deposition processes may be used. The thickness of the gate dielectric layer 30L may be in a range from 1 nm to 20 nm, such as from 2 nm to 10 nm, although lesser and greater thicknesses may also be used.

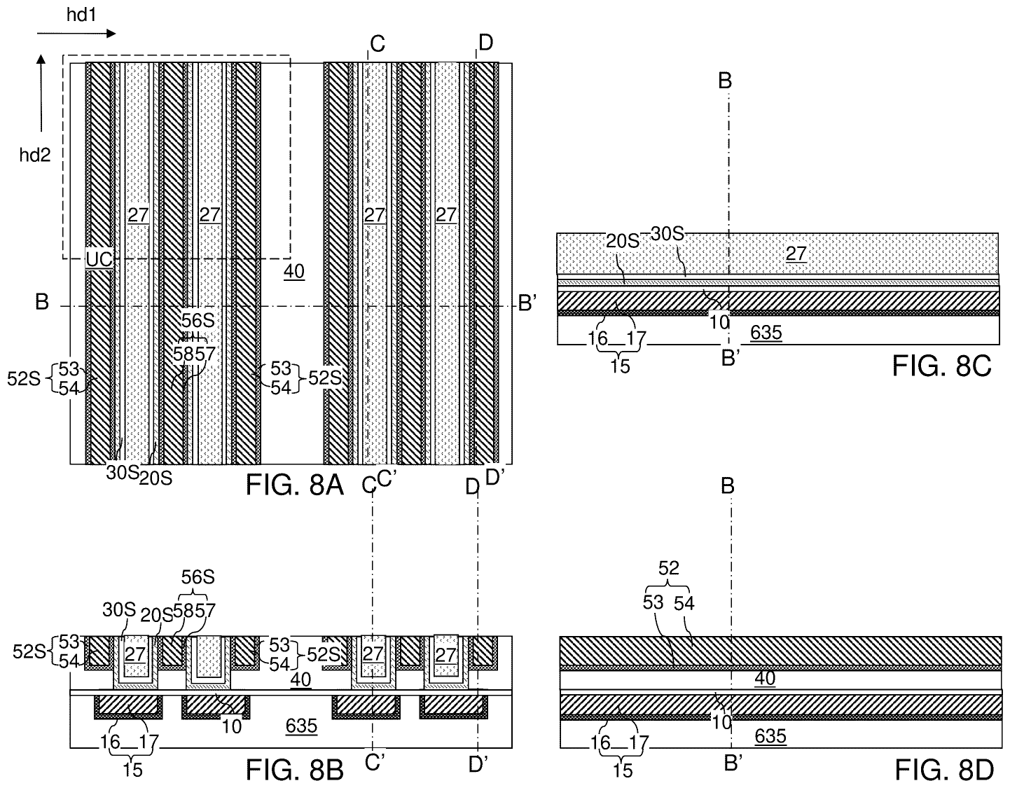

Referring to FIGS. 8A-8D, etch mask material portions 27 may be formed within unfilled volumes of the channel cavities 23 as formed at the processing steps of FIGS. 6A-6D. Thus, the etch mask material portions 27 may be formed over the gate dielectric layer 30L, and fill volumes of the channel cavities 23 that remain unfilled after formation of the gate dielectric layer 30L. In one embodiment, the etch mask material portions 27 may comprise a self-planarizing material or a material that may be planarized. For example, the etch mask material of the etch mask material portions 27 may be applied within the unfilled volumes of the channel cavities 23, and excess portions of the etch mask material may be removed from above the horizontal plane including the top surface of the gate dielectric layer 30L. In one embodiment, the etch mask material may comprise a photoresist material, amorphous carbon, diamond-like carbon (DLC), a semiconductor material (such as amorphous silicon or polysilicon), or a polymer material. Optionally, the top surfaces of the etch mask material portions 27 may be vertically recessed below the horizontal plane including the top surface of the gate dielectric layer 30L.

Portions of the gate dielectric layer 30L and the channel material layer 20L that overlie the horizontal plane including the top surface of the insulating matrix layer 40 may be removed by a planarization process. In one embodiment, the planarization process may comprise a first selective etch process that vertically recesses the material of the gate dielectric layer 30L selective to the material of the channel material layer 20L, and a second selective etch process that vertically recesses the material of the channel material layer 20L selective to the materials of the source strips 52S, the drain strips 56S, and the insulating matrix layer 40. The first selective etch process may comprise an isotropically etch process (such as a wet etch process) or an anisotropic etch process (such as a reactive ion etch process). The second selective etch process may comprise an isotropically etch process (such as a wet etch process) or an anisotropic etch process (such as a reactive ion etch process). In this embodiment, portions of the gate dielectric layer 30L and the channel material layer 20L overlying the horizontal plane including the top surface of the insulating matrix layer 40 may be removed using the etch mask material portions 27 as an etch mask.

Alternatively, the planarization process may comprise a chemical mechanical polishing (CMP) process that sequentially removes horizontally-extending portions of the gate dielectric layer 30L and the channel material layer 20L from above the horizontal plane including the top surface of the insulating matrix layer 40.

Each patterned portion of the gate dielectric layer 30L constitutes a gate dielectric strip 30S. Each of the gate dielectric strips 30S may be located within a respective channel cavity, and may have a respective U-shaped vertical cross-sectional shape within vertical planes laterally extending along the first horizontal direction hd1. Each patterned portion of the channel material layer 20L constitutes a channel material strip 20S. Each of the channel material strips 20S may be located within a respective channel cavity, and may have a respective U-shaped vertical cross-sectional shape within vertical planes laterally extending along the first horizontal direction hd1. Top surfaces of the source strips 52S and the drain strips 56S are physically exposed after the planarization process.

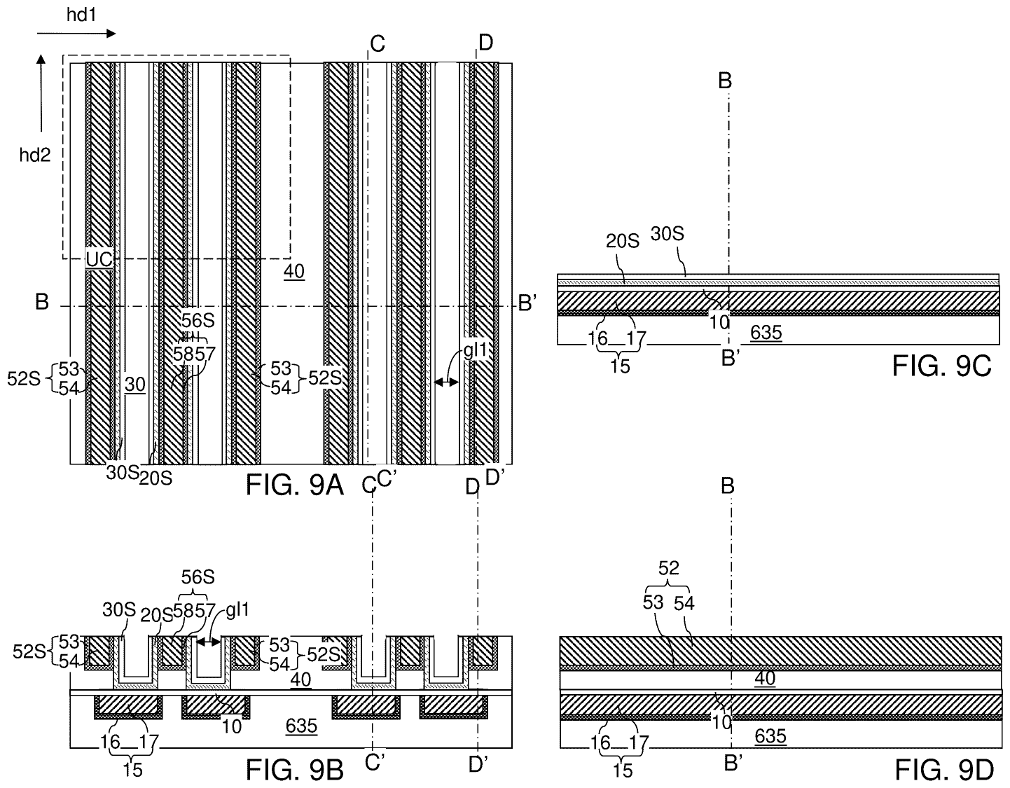

Referring to FIGS. 9A-9D, the etch mask material portions 27 may be removed selective to the materials of the gate dielectric strips 30S, the channel material strips 20S, the source strips 52S, the drain strips 56, and the insulating matrix layer 40. For example, if the etch mask material portions 27 comprise a photoresist material, an ashing process may be used to remove the etch mask material portions 27. Gate trenches are formed in volumes from which the etch mask material portions 27 are removed. In one embodiment, each of the gate trenches may have a uniform width along the first horizontal direction hd1, which is herein referred to as a first gate length gl1.

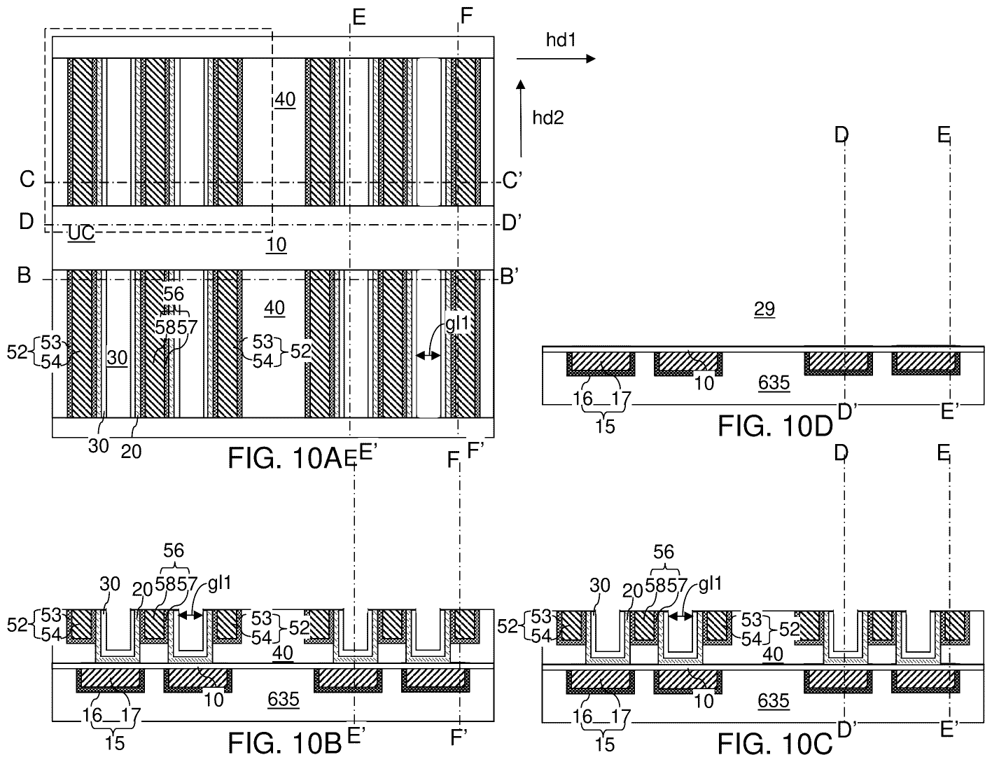

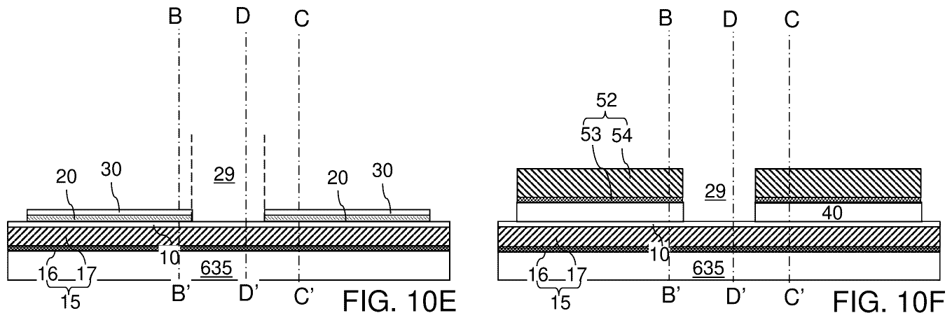

Referring to FIGS. 10A-10F, a photoresist layer (not shown) may be applied over the insulating matrix layer 40, the source strips 52S, the drain strips 56S, the gate dielectric strips 30S, and the channel material strips 20S, and may be lithographically patterned to form line-shaped openings that laterally extend along the first horizontal direction hd1. The spacing between neighboring pairs of the line-shaped openings in the photoresist layer may be the same as the width of the transistors (e.g., TFTs) to be subsequently formed along the second horizontal direction hd2. In one embodiment, the spacing between neighboring pairs of the line-shaped openings in the photoresist layer may be in a range from 10 nm to 1,000 nm, such as from 30 nm to 300 nm, although lesser and greater spacings may also be used. The width of each line-shaped opening along the second horizontal direction hd2 is the spacing between neighboring pairs of field effect transistors to be subsequently formed along the second horizontal direction hd2. The width of each line-shaped opening along the second horizontal direction hd2 may be in a range from 2 nm to 500 nm, such as from 10 nm to 200 nm, although lesser and greater widths may also be used.

A sequence of etch processes may be performed to transfer the pattern of the line-shaped openings in the photoresist layer through the combination of the insulating matrix layer 40, the source strips 52S, the drain strips 56S, the gate dielectric strips 30S, and the channel material strips 20S. The sequence of etch processes may comprise a first etch process that etches unmasked portions of the gate dielectric strips 30S that are not covered by the photoresist layer selective to the material of the channel material strips 20S, a second etch process that etches unmasked portions of the insulating matrix layer 40 that are not covered by the photoresist layer selective to the material of the bottom gate dielectric layer 10, and a third etch process that etches unmasked portions of the channel material strips 20S selective to the material of the bottom gate dielectric layer 10. The first etch process may comprise an isotropic etch process or an anisotropic etch process. The second etch process may comprise an anisotropic etch process. The third etch process may comprise an isotropic etch process or an anisotropic etch process.

Isolation trenches 29 replicating the pattern of the line-shaped openings in the photoresist layer may be formed through the combination of the insulating matrix layer 40, the source strips 52S, the drain strips 56S, the gate dielectric strips 30S, and the channel material strips 20S such that a top surface segment of the bottom gate dielectric layer 10 is a physically exposed at the bottom of each isolation trench 29. The isolation trenches 29 divide the source strips 52S, the drain strips 56S, the gate dielectric strips 30S, and the channel material strips 20S into source regions 52, drain regions 56, U-shaped gate dielectrics 30, and U-shaped channel plates 20, respectively. The photoresist layer may be subsequently removed, for example, by ashing.

Generally, the gate dielectric layer 30L, the channel material layer 20L, the source strips 52S, and the drain strips 56S may be patterned by forming isolation trenches 29 laterally extending along the first horizontal direction hd1. A combination of source regions 52, drain regions 56, U-shaped channel plates 20, and U-shaped gate dielectric 30 is formed between each neighboring pair of the isolation trenches 29. Each U-shaped channel plate 20 contacts sidewalls of a source region 52 and a drain region 56, and has a bottom surface located at, or below, a horizontal plane including bottom surfaces of the source regions 52 and the drain regions 56. Each U-shaped gate dielectric 30 contacts inner sidewalls of a respective U-shaped channel plate 20. In one embodiment, the bottom surface of the horizontally-extending portion of each U-shaped channel plate 20 may be located below the horizontal plane including the bottom surfaces of the source regions 52 and the drain regions 56, and may contact a top surface of a bottom gate dielectric layer 10 that overlies the bottom gate electrodes 15.

Generally, the source regions 52 and the drain regions 56 may be located within the insulating matrix layer 40. A U-shaped channel plate 20 is disposed between each neighboring pair of a source region 52 and a drain region 56. Each U-shaped channel plate 20 comprises a first vertically-extending portion contacting a sidewall of the source region 52, a second vertically-extending portion contacting a sidewall of the drain region 56, and a horizontally-extending portion connecting bottom ends of the first vertically-extending portion and the second vertically-extending portion and having a bottom surface located at, or below, a horizontal plane including bottom surfaces of the source region 52 and the drain region 56. A U-shaped gate dielectric 30 may contact inner sidewalls of the first vertically-extending portion and the second vertically-extending portion of each U-shaped channel plate 20, and may contact a top surface of the horizontally-extending portion of each U-shaped channel plate 20.

In one embodiment, a topmost surface of each U-shaped gate dielectric 30 may be located at, or below, a horizontal plane including top surfaces of the source regions 52 and the drain regions 56. In one embodiment, top surfaces of the first vertically-extending portion and the second vertically-extending portion of each U-shaped channel plate 20 may be located at, or below, the horizontal plane including the top surfaces of the source regions 52 and the drain regions 56.

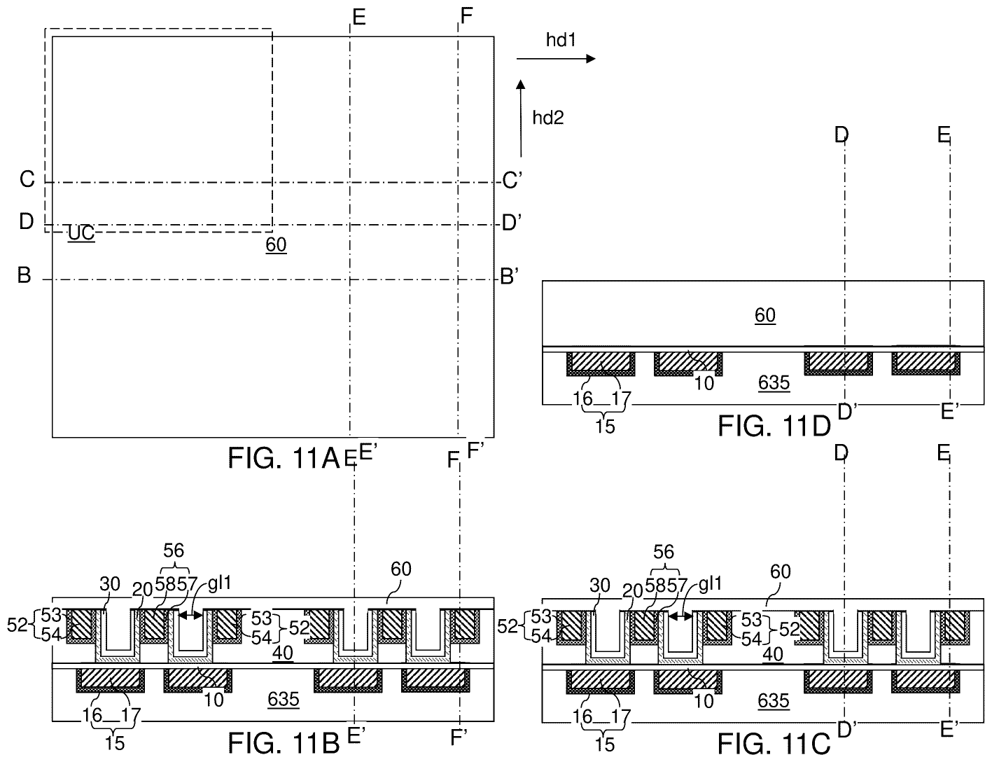

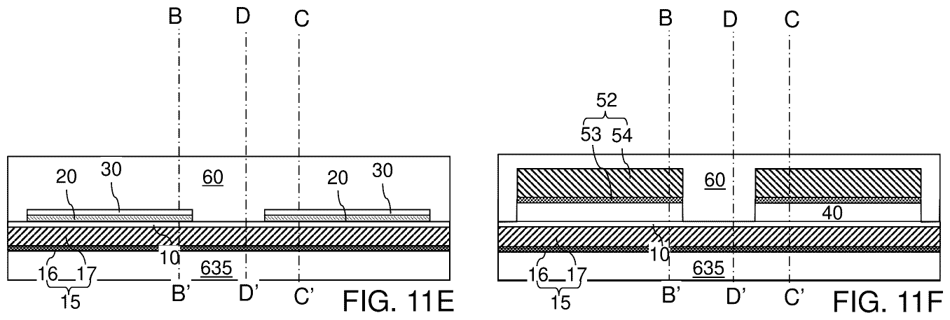

Referring to FIGS. 11A-11F, a dielectric fill material that is different from the dielectric material of the U-shaped gate dielectrics 30 may be deposited in the isolation trenches 29 and in the gate trenches. In one embodiment, the dielectric fill material may comprise a different dielectric material than the insulating matrix layer 40. For example, the dielectric fill material may comprise a doped silicate glass having an etch rate in 100:1 dilute hydrofluoric acid that is at least 10 times, such as 100 or more times, the etch rate of the dielectric material of the insulating matrix layer 40. In an illustrative example, the dielectric fill material may comprise borosilicate glass, porous or non-porous organosilicate glass, or a spin-on glass. The dielectric fill material may comprise a self-planarizing dielectric material or a dielectric material that may be planarized, for example, by chemical mechanical polishing.

The dielectric fill material forms a dielectric isolation layer 60 that fills the isolation trenches 29 and the gate trenches. In other words, the dielectric isolation layer 60 in the isolation trenches 29 and in volumes of the channel cavities 23 are not filled with the U-shaped channel plates 20 and the U-shaped gate dielectrics 30. The dielectric isolation layer 60 may be formed with a planar horizontal top surface. The thickness of the dielectric isolation layer 60, as measured between a horizontal top surface and an interface with the top surface of the insulating matrix layer 40, maybe in a range from 10 nm to 500 nm, such as from 20 nm to 300 nm, and/or from 40 nm to 150 nm, although lesser and greater thicknesses may also be used.

Generally, the dielectric isolation layer 60 fill all volumes of the gate trenches and the isolation trenches 29. Thus, the dielectric isolation layer 60 fills all volumes that are laterally bounded by inner side walls of a respective U-shaped gate dielectric 30 along the first horizontal direction hd1 and located within the area of the respective U-shaped gate dielectric 30.

In one embodiment, the topmost surface of each U-shaped gate dielectric 30 may be located below the horizontal plane including the top surface of the dielectric isolation layer 60. In one embodiment, the dielectric isolation layer 60 laterally surrounds the source regions 52 and the drain regions 56, and contacts sidewalls of the source regions 52 and the drain regions 56. Specifically, the dielectric isolation layer 60 make contact each sidewall of the source regions 52 and the drain regions 56 that laterally extending along the first horizontal direction hd1. The dielectric isolation layer 60 contacts each inner sidewall of vertically-extending portions of the U-shaped gate dielectrics 30, and contacts the top surface of the horizontally-extending portion of the U-shaped gate dielectrics 30.

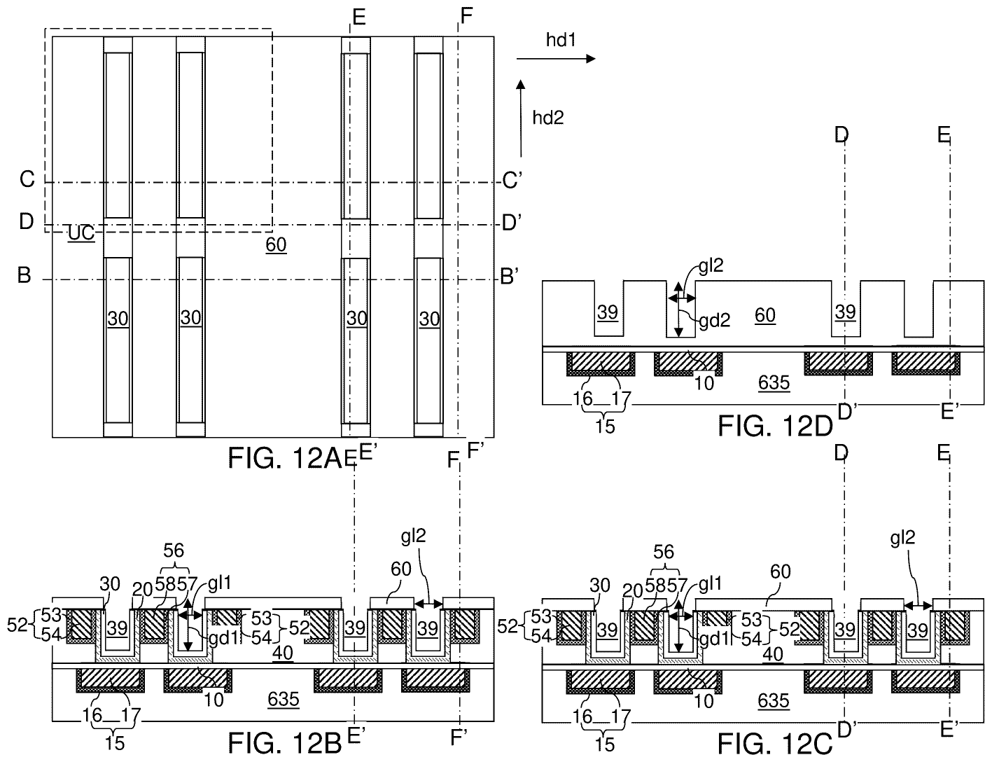

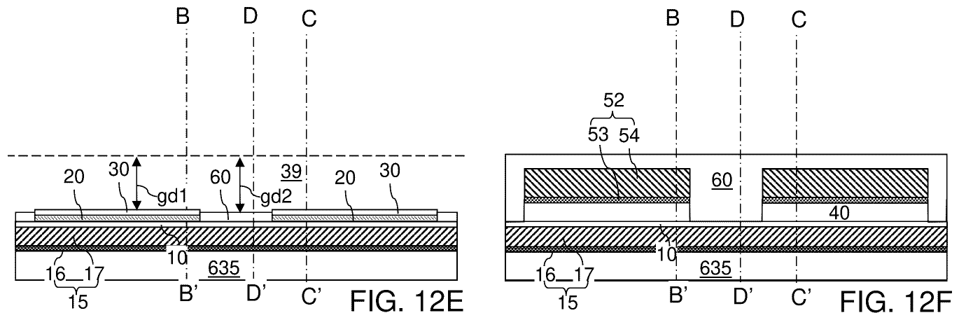

Referring to FIGS. 12A-12F, a photoresist layer (not shown) may be applied over the top surface of the dielectric isolation layer 60, and may be lithographically patterned to form line-shaped openings that laterally extend along the second horizontal direction hd2. Each line-shaped opening may have a uniform width along the first horizontal direction hd1 that is not less than the first gate length gl1. The uniform width that along the first horizontal direction hd1 of each line-shaped opening in the photoresist layer is a herein referred to as a second gate length gl2. The second gate length gl2 may be greater than the first gate length gl1, and it may be less than the sum of the first gate length gl1 and twice the thickness of each vertically-extending portion of the U-shaped gate dielectrics 30. In one embodiment, the lengthwise edges of each line-shaped opening in the photoresist layer may be located within the area of the topmost surface of a vertically-extending portion of a respective U-shaped gate dielectric 30.

An anisotropic etch process may be performed to etch the unmasked portions of the dielectric isolation layer 60 selective to the material of the U-shaped gate dielectrics 30. The duration of the anisotropic etch process may be selected such that the entirety of the portions of the dielectric isolation layer 60 overlying the U-shaped gate dielectrics 30 is removed. All inner sidewalls of the vertically-extending portions of the U-shaped gate dielectrics 30 and all top surfaces of the horizontally-extending portions of the U-shaped gate dielectrics 30 may be physically exposed after the anisotropic etch process.

In one embodiment, the duration of the anisotropic etch process may selected such that a remaining portion of the dielectric isolation layer 60 remains between a pair of a physically exposed top surfaces of the horizontally-extending portions of the U-shaped gate dielectrics 30 that are laterally spaced apart along the second horizontal direction hd2. Alternatively, the duration of the anisotropic etch process may be selected such that a portion of the top surface of the bottom gate dielectric layer 10 is physically exposed between a pair of a physically exposed top surfaces of the horizontally-extending portions of the U-shaped gate dielectrics 30 that are laterally spaced apart along the second horizontal direction hd2. The photoresist layer may be subsequently removed, for example, by ashing.

Each void laterally bounded by inner sidewalls of a column of U-shaped gate dielectrics 30 arranged along the second horizontal direction hd2 constitutes a gate cavity 39. The lateral width of each gate cavity 39 between a pair of inner sidewalls of a U-shaped gate dielectric 30 is the first gate length gl1. The lateral width of each gate cavity 39 between a pair of sidewalls of the dielectric isolation layer 60 is the second gate length gl2, which may be greater than the first gate length gl1.

Generally, the gate cavities 39 may be formed by removing first portions of the dielectric isolation layer 60 having an areal overlap with horizontally-extending portions of the U-shaped gate dielectrics 30 and by removing second portions of the dielectric isolation layer 60 located between neighboring pairs of the first portions of the dielectric isolation layer 60. In one embodiment, the gate cavities 39 may be formed by applying and patterning a photoresist layer over the dielectric isolation layer 60 such that the first portions of the dielectric isolation layer 60 and the second portions of the dielectric isolation layer 60 are not masked by the photoresist layer, and by etching unmasked portions of the dielectric isolation layer 60 selective to the material of the U-shaped gate dielectrics 30, which is the same as the material of the gate dielectric layer 30L.

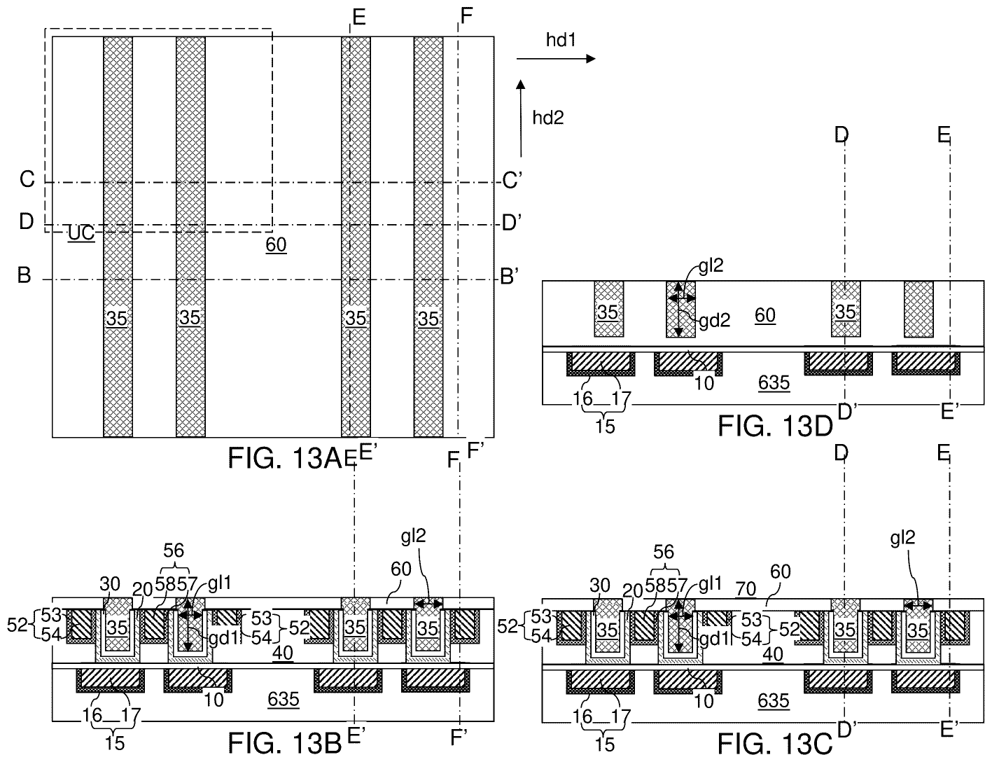

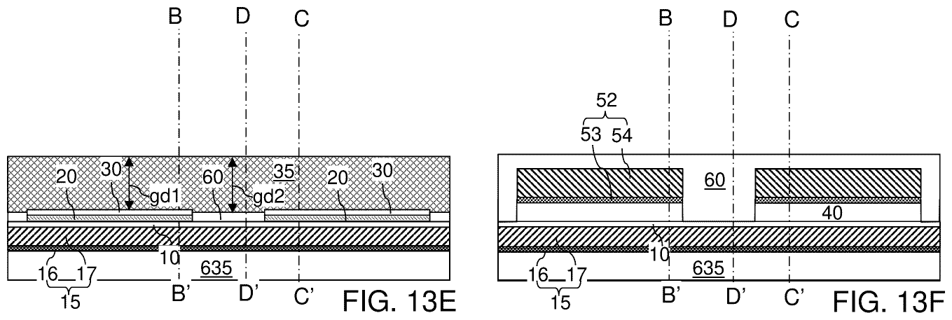

Referring to FIGS. 13A-13F, a gate electrode material may be deposited within the gate cavities 39. The gate electrode material may comprise any conductive material that may be used for a gate electrode. For example, the gate electrode material may comprise at least one metallic material and/or at least one heavily-doped semiconductor material. In one embodiment, the gate electrode material may comprise one or more metal gate materials known in the art, such as TiN, TaN, WN, Ti, Ta, W, Nb, etc. Excess portions of the gate electrode material may be removed from above the horizontal plane including the top surface of the dielectric isolation layer 60 by a planarization process. For example, a chemical mechanical polishing process and/or are recess etch process may be used to remove portions of the gate electrode material from above the horizontal plane including the top surface of the dielectric isolation layer 60. Each remaining portion of the gate electrode material filling a respective gate cavity 39 constitutes a gate electrode line that includes gate electrodes 35 for a column of transistors (e.g., TFTs) arranged along the second horizontal direction hd2. A plurality of gate electrode lines including a respective set of gate electrodes 35 may be formed in the gate cavities 39.

Generally, at least the first portions of the dielectric isolation layer 60 located within the U-shaped channel plates 20 may be replaced with the gate electrodes 35 to form field effect transistors, which may be thin film transistors. In one embodiment, a two-dimensional array of thin film transistors may be arranged as a rectangular array extending along the first horizontal direction hd1 and along the second horizontal direction hd2. Each gate electrode 35 may contact inner sidewalls of a respective U-shaped gate dielectric 30 and a top surface of a horizontally-extending bottom portion of the respective U-shaped gate dielectric 30. Each set of gate electrodes 35 arranged along the second horizontal direction may be merged as a respective gate electrode line that continuously extends along the second horizontal direction hd2 over multiple areas of unit cells UC.

In one embodiment, the dielectric isolation layer 60 overlies the source regions 52 and the drain regions 56. A top surface of each gate electrode 35 may be located within a horizontal plane including a top surface of the dielectric isolation layer 60.

In one embodiment, the source region 52 and the drain region 56 of each transistor (e.g., TFT) may be laterally spaced apart along a first horizontal direction hd1, and a portion of the gate electrode 35 located between the first vertically-extending portion and the second vertically-extending portion of the U-shaped gate dielectric 30 has a first gate length gl1 along the first horizontal direction hd1. In one embodiment, a portion of the gate electrode 35 laterally extending outside an area of the U-shaped gate dielectric 30 in a plan view has a second gate length gl2 along the first horizontal direction hd1 that is greater than the first gate length hd1. This is caused by the transfer of the pattern of the line-shaped openings in the photoresist layer through the dielectric isolation layer 60 at the processing steps of FIGS. 12A-12F without reduction of the dimension along the first horizontal direction hd1, while the U-shaped gate dielectrics 30 reduce the lateral extent of the gate cavity 39 along the first horizontal direction hd1 within the areas of the U-shaped gate dielectrics 30 in a plan view.

Generally, the depth of the gate cavities 39 may be greater outside the areas of the U-shaped gate dielectrics 30 in a plan view because the U-shaped gate dielectrics 30 function as etch stop structures during formation of the gate cavities 39 at the processing steps of FIGS. 12A-12F. In this embodiment, the portion of each gate electrode 35 located between the first vertically-extending portion and the second vertically-extending portion of an underlying U-shaped gate dielectric 30 has a first gate depth gd1 along a vertical direction (as measured between the top surface of the gate electrode 35 and a bottom surface of the gate electrode 35 contacting the horizontally-extending portion of the underlying U-shaped gate dielectric 30). The portion of each gate electrode 35 laterally extending outside the area of the U-shaped gate dielectrics 30 in the plan view has a second gate depth gd2 along the vertical direction that is greater than the first gate depth gd1. The second gate depth gd2 may be measured between the top surface of the gate electrode 35 and an interface with a recessed horizontal surface of the dielectric isolation layer 60.

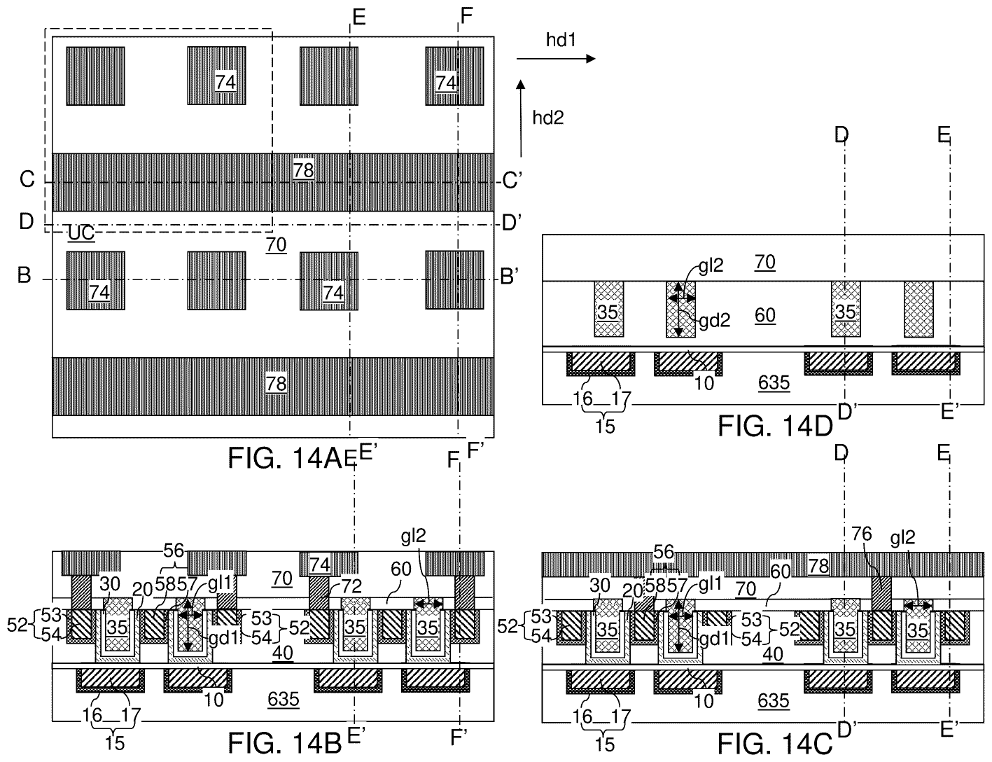

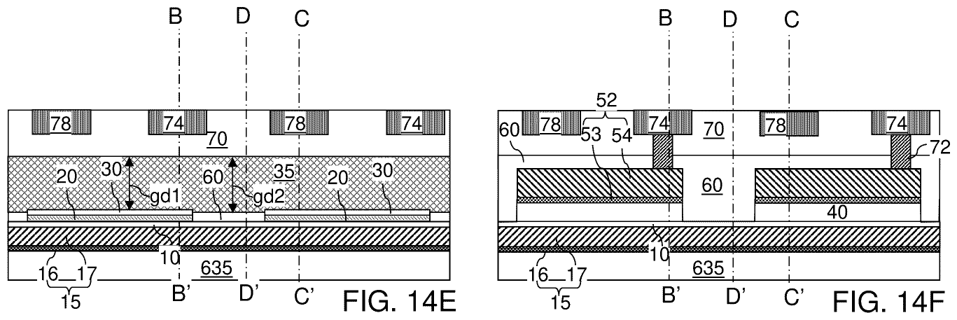

Referring to FIGS. 14A-14F, at least one first upper-level dielectric material layer 70 and first upper-level metal interconnect structures (72, 74, 76, 78) may be formed over the insulating matrix layer 40. The at least one first upper-level dielectric material layer 70 may include a first via-level dielectric material layer laterally surrounding source contact via structures 72 and drain contact via structures 76, and a first line-level dielectric material layer laterally surrounding first source connection pads 74 and bit lines 78. Each source contact via structure 72 contacts a respective source region 52, and vertically extends through the dielectric isolation layer 60 and the first via-level dielectric material layer. Each drain contact via structure 76 contacts a respective drain region 56, and vertically extends through the dielectric isolation layer 60 and the first via-level dielectric material layer. Each first source connection pad 74 contacts a top surface of a respective source contact via structure 72. Each bit line 78 contacts a respective row of drain contact via structures 76 arranged along the first horizontal direction hd1.

In one embodiment, the first via-level dielectric material layer may be formed first, and the source contact via structures 72 and the drain contact via structures 76 may be formed through the first via-level dielectric material layer. The first line-level dielectric material layer may be subsequently formed over the first via-level dielectric material layer, and the first source connection pads 74 and the bit lines 78 may be subsequently formed through the first line-level dielectric material layer on a respective one of the source contact via structures 72 and the drain contact via structures 76.

Alternatively, the first via-level dielectric material layer and the first line-level dielectric material layer may be formed as a single dielectric material layer, and a dual damascene process may be performed to form integrated line and via structures. The integrated line and via structures include source-side integrated line and via structures including a respective combination of a source contact via structure 72 and a first source connection pad 74, and drain-side integrated line and via structures including a respective combination of drain contact via structures 76 and a bit line 78 that is integrally formed within the drain contact via structures 76. Generally, each bit line 78 laterally extends along the first horizontal direction hd1 and may be electrically connected to a set of drain regions 56 that are arranged along the first horizontal direction hd1.

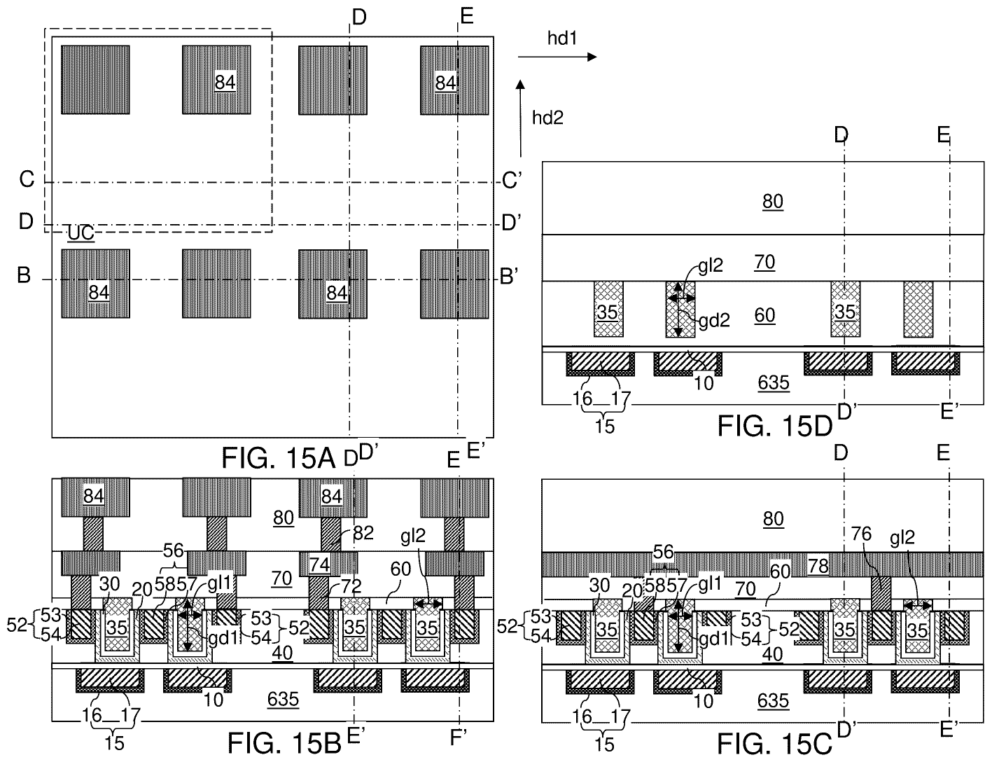

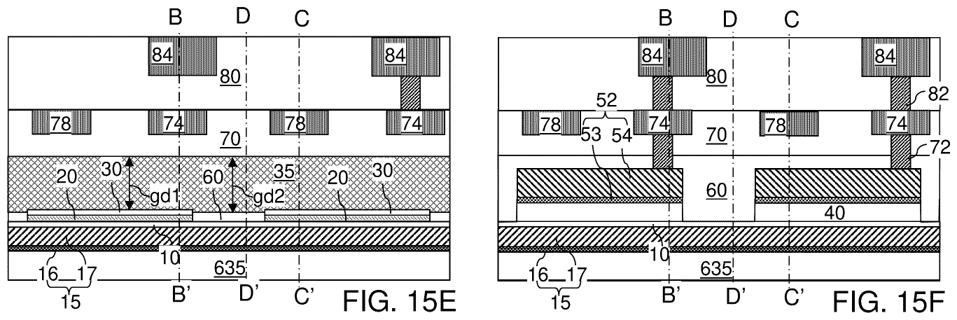

Referring to FIGS. 15A-15F, at least one second upper-level dielectric material layer 80 and second upper-level metal interconnect structures (82, 84) may be formed over the at least one first upper-level dielectric material layer 70. The at least one second upper-level dielectric material layer 80 may include a second via-level dielectric material layer laterally surrounding source connection via structures 82, and a second line-level dielectric material layer laterally surrounding second source connection pads 84. In this embodiment, the second via-level dielectric material layer may be formed, and the source connection via structures 82 may be formed through the second via-level dielectric material layer. The second line-level dielectric material layer may be subsequently formed over the second via-level dielectric material layer, and the second source connection pads 84 may be subsequently formed through the second line-level dielectric material layer on a respective one of the source connection via structures 82.

Alternatively, the second via-level dielectric material layer and the second line-level dielectric material layer may be formed as a single dielectric material layer, and a dual damascene process may be performed to form integrated line and via structures. The integrated line and via structures include source-side integrated line and via structures including a respective combination of a source connection via structure 82 and a second source connection pad 84.

Generally, upper-level dielectric material layers (70, 80) may be formed over the insulating matrix layer 40. Source-connection metal interconnect structures (72, 74, 82, 84) may be formed within the upper-level dielectric material layers (70, 80), which may be used to electrically connect each of the source regions 52 to a conductive node of a respective capacitor structure to be subsequently formed. Within each unit cell UC, first source-connection metal interconnect structures (72, 74, 82, 84) may be used to provide electrical connection between a first source region 52 to a first conductive node of a first capacitor structure to be subsequently formed, and second source-connection metal interconnect structures (72, 74, 82, 84) may be used to provide electrical connection between a second source region 52 and a second conductive node of a second capacitor structure to be subsequently formed.

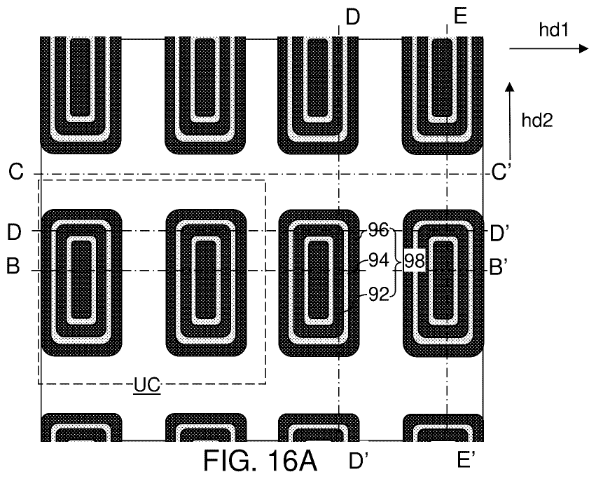

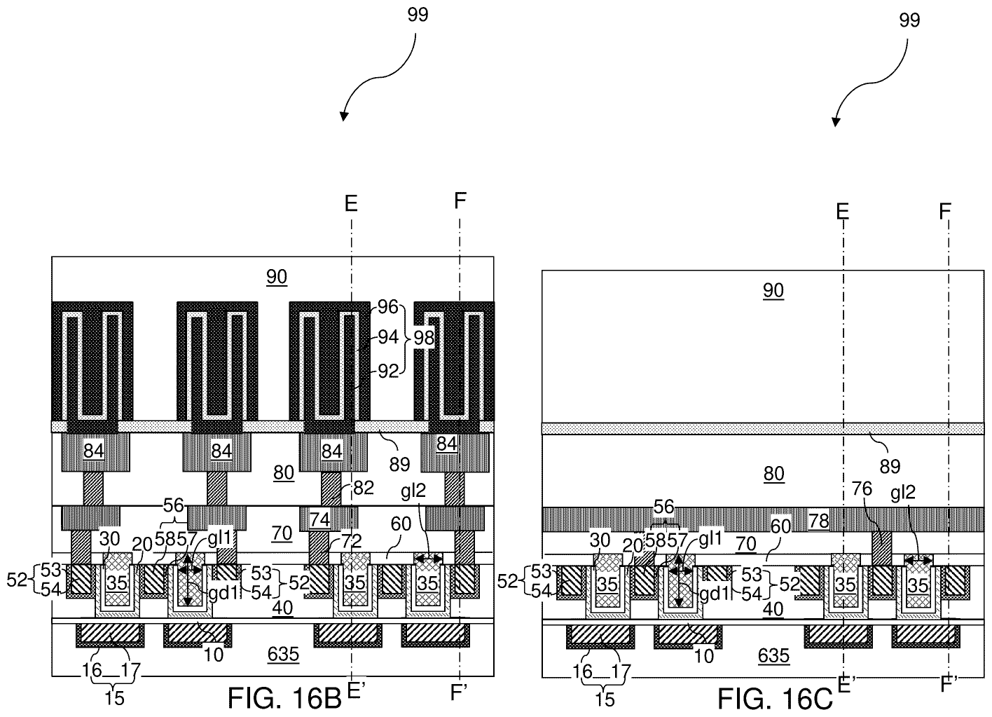

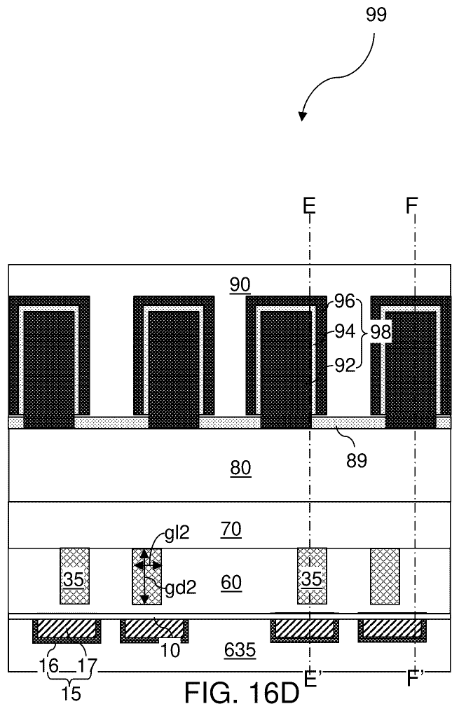

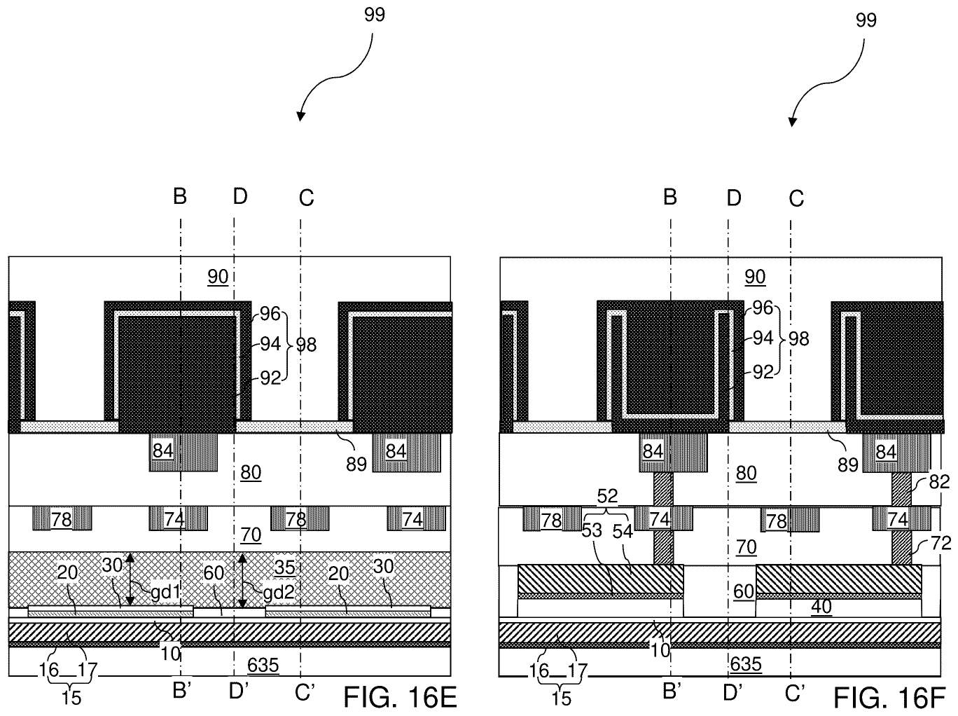

Referring to FIGS. 16A-16F, capacitor structures 98 and a capacitor-level dielectric material layer 90 may be formed. For example, first capacitor plates 92 may be formed on top surfaces of the second source connection pads 84 by deposition and patterning a first conductive material, which may be a metallic material or a heavily doped semiconductor material. Optionally, a dielectric etch stop layer 89 may be formed on a top surface of the second upper-level dielectric material layer 80. A node dielectric 94 may be formed on each first capacitor plate 92 by deposition of a node dielectric material such as silicon oxide and/or a dielectric metal oxide (e.g., aluminum oxide, lanthanum oxide, and/or hafnium oxide). A second capacitor plate 96 may be formed on physically exposed surfaces of the node dielectric by deposition and pattering of a second conductive material, which may be a metallic material or a heavily doped semiconductor material.

Each contiguous combination of a first capacitor plate 92, a node dielectric 94, and a second capacitor plate 96 may constitute a capacitor structure 98. A pair of capacitor structures 98 may be formed within each unit cell UC. Thus, a first capacitor structure 98 and a second capacitor structure 98 may be formed within each unit cell UC. A first conductive node (such as a first capacitor plate 92) of the first capacitor structure 98 is electrically connected to an underlying first source region 52, and a second conductive node (such as another first capacitor plate 92) of the second capacitor structure 98 is electrically connected to an underlying second source region 52.

The capacitor-level dielectric material layer 90 may be formed over the capacitor structures 98. Each of the capacitor structures 98 may be formed within, and laterally surrounded by, the capacitor-level dielectric material layer 90, which is one of the upper-level dielectric material layers (70, 80, 90). A two-dimensional array of memory cells 99 may be formed.

In one embodiment, each of the first capacitor plates 92 may be electrically connected to (i.e., electrically shorted to) a respective one of the source regions 52. Each of the second capacitor plates 96 may be electrically grounded, for example, by forming an array of conductive via structures (not shown) that contact the second capacitor plates 96 and connected to an overlying metallic plate (not shown).

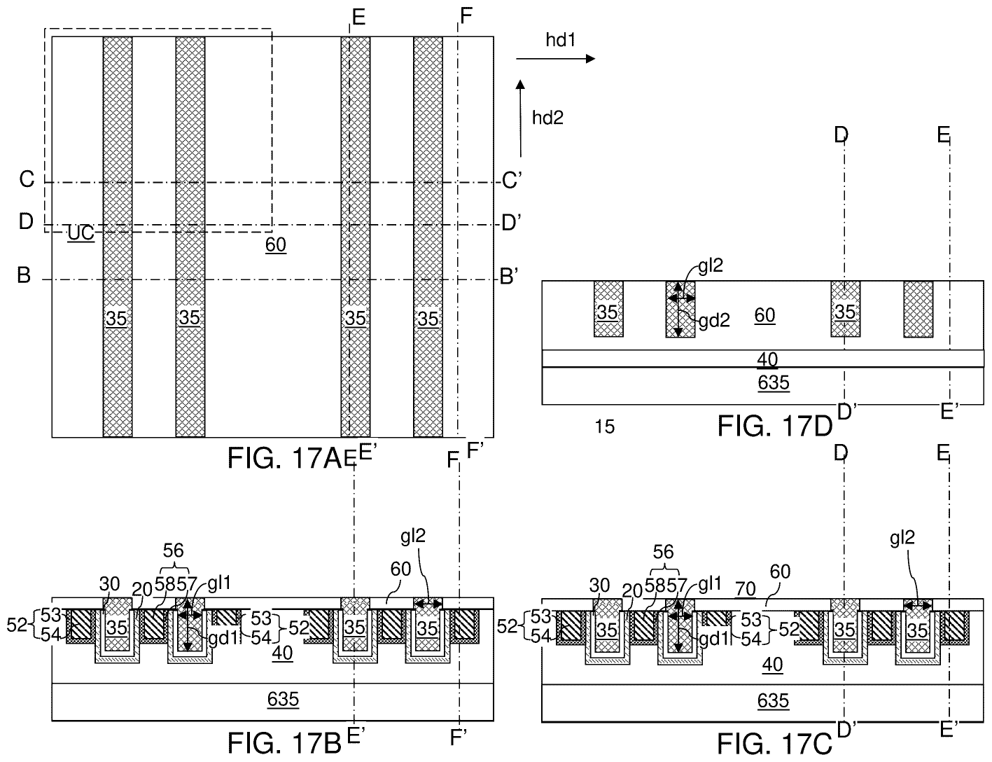

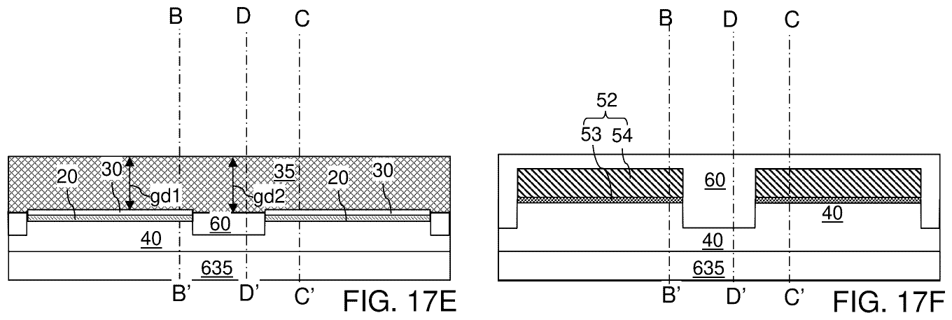

Referring to FIGS. 17A-17F, a second exemplary structure according to a second embodiment of the present disclosure may be derived from the first exemplary structure illustrated in FIGS. 13A-13F by omitting formation of the bottom gate electrodes 15 and the bottom gate dielectric layer 10. In this embodiment, the depth of the channel cavities 23 may be determined by controlling the duration of the anisotropic etch process that forms the channel cavities 23. A recessed horizontal surface of the insulating matrix layer 40 may be physically exposed at the bottom of each channel cavity 23. The bottom surface of the horizontally-extending portion of each U-shaped channel plate 20 contacts a respective recessed horizontal surface of the insulating matrix layer 40.

In one embodiment, the source region 52 and the drain region 56 of each thin film transistor are laterally spaced apart along a first horizontal direction hd1, and a portion of the gate electrode 35 located between the first vertically-extending portion and the second vertically-extending portion of the U-shaped gate dielectric 30 has a first gate length gl1 along the first horizontal direction hd1. In one embodiment, a portion of the gate electrode 35 laterally extending outside an area of the U-shaped gate dielectric 30 in a plan view has a second gate length gl2 along the first horizontal direction hd1 that is greater than the first gate length gl1.

Generally, the depth of the gate cavities 39 may be greater outside the areas of the U-shaped gate dielectrics 30 in a plan view. In this embodiment, the portion of each gate electrode 35 located between the first vertically-extending portion and the second vertically-extending portion of an underlying U-shaped gate dielectric 30 has a first gate depth gd1 along a vertical direction (as measured between the top surface of the gate electrode 35 and a bottom surface of the gate electrode 35 contacting the horizontally-extending portion of the underlying U-shaped gate dielectric 30). The portion of each gate electrode 35 laterally extending outside the area of the U-shaped gate dielectrics 30 in the plan view has a second gate depth gd2 along the vertical direction that is greater than the first gate depth gd1. The second gate depth gd2 may be measured between the top surface of the gate electrode 35 and an interface with a recessed horizontal surface of the dielectric isolation layer 60.

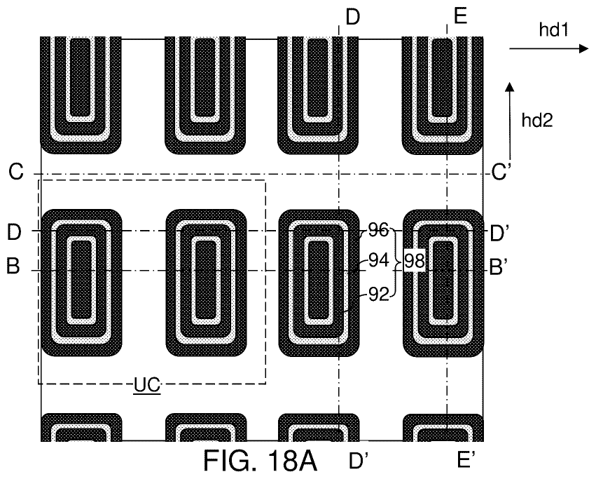

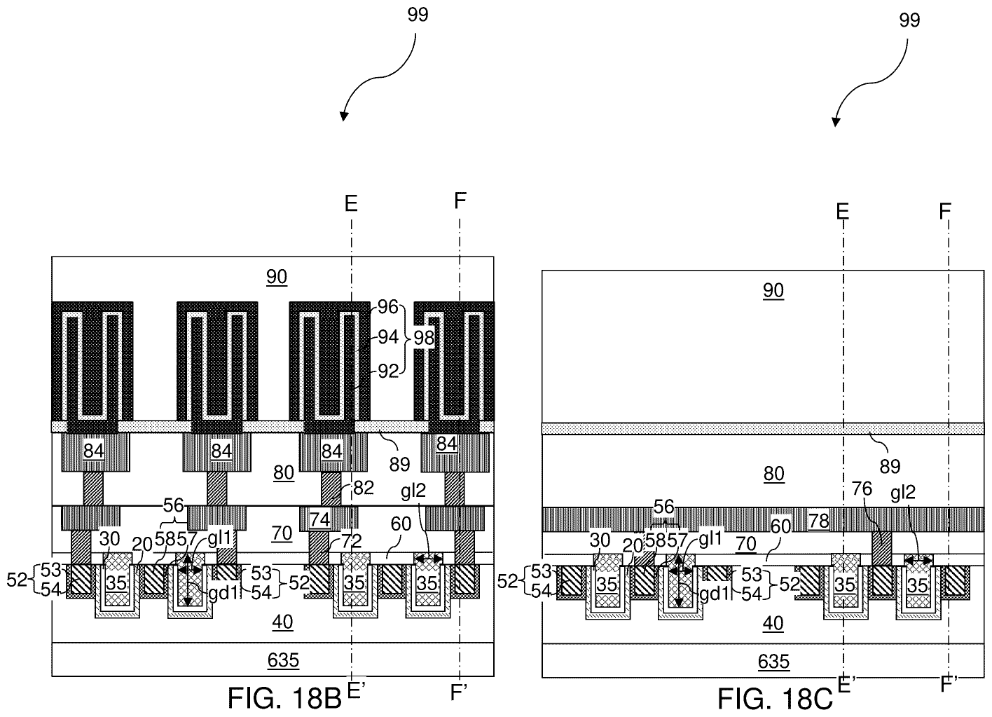

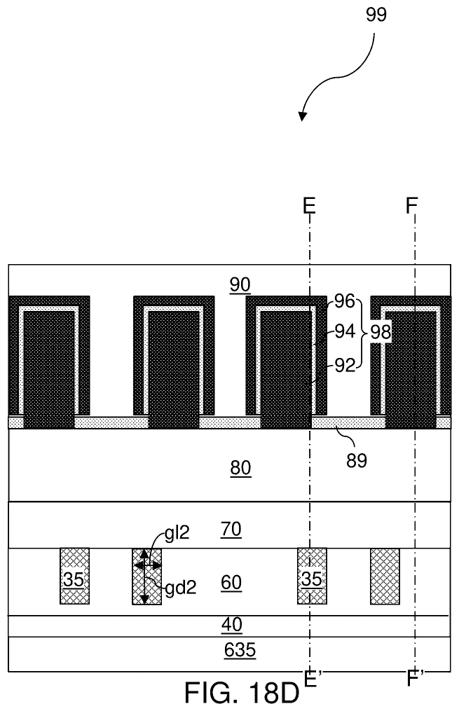

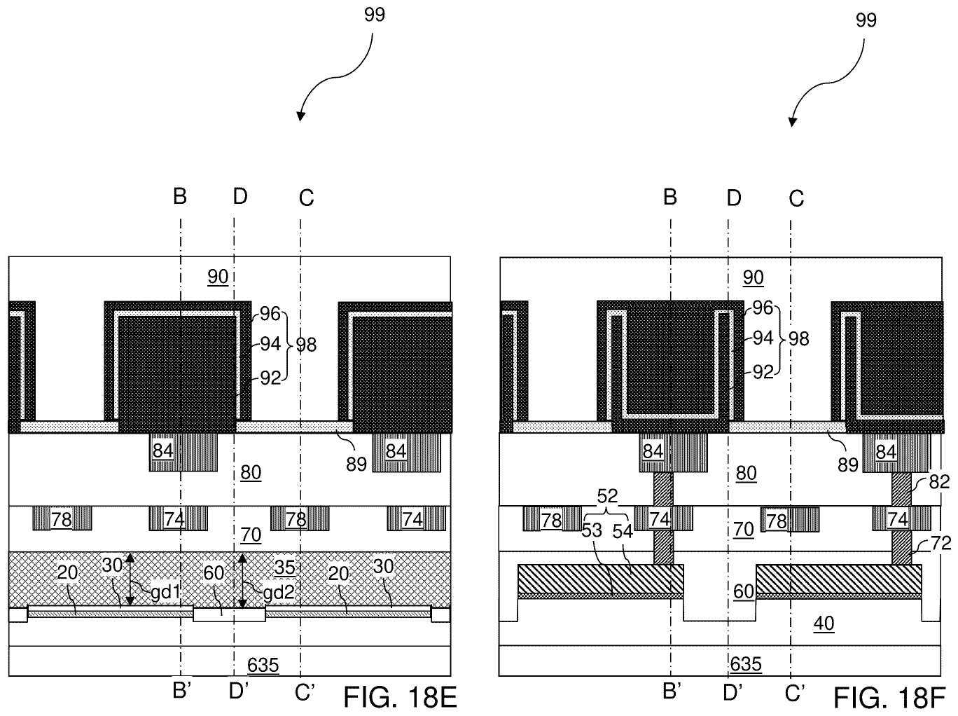

Referring to FIGS. 18A-18F, the processing steps of FIGS. 14A-14F, 15A-15F, and 16A-16F may be performed to form various metal interconnect structures and capacitor structures 98. A two-dimensional array of memory cells 99 may be formed. In one embodiment, a dynamic random access memory may be provided, which uses thin film transistors including U-shaped channel plates 20.

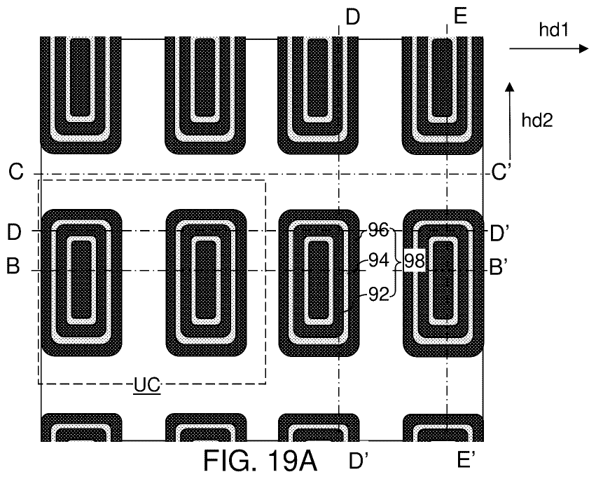

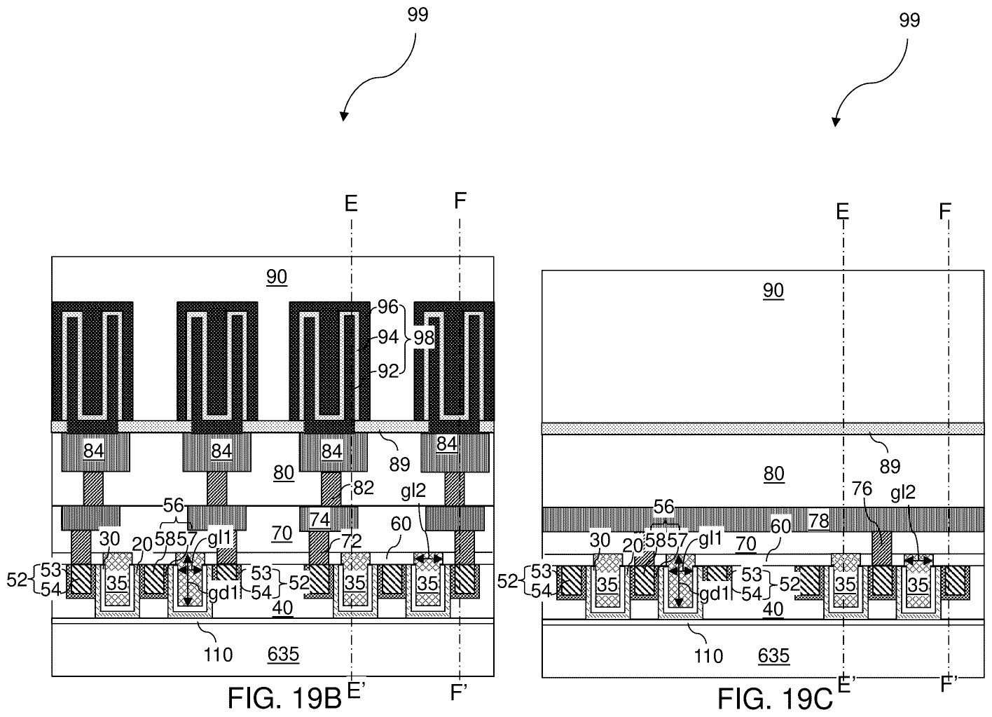

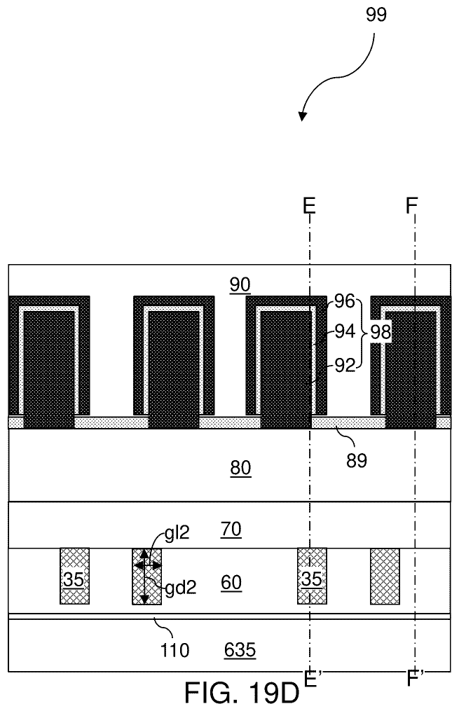

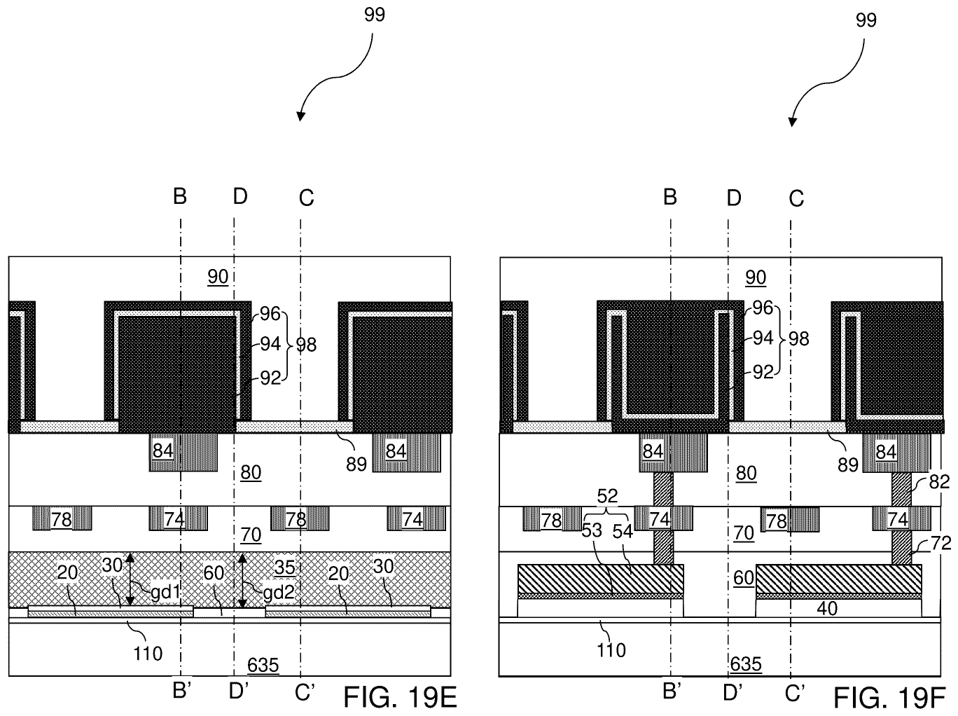

Referring to FIGS. 19A-19F, a third exemplary structure according to a third embodiment of the present disclosure may be derived from the first exemplary structure illustrated in FIGS. 16A-16F by omitting formation of the bottom gate electrodes 15 and by replacing the bottom gate dielectric layer 10 with an etch stop dielectric layer 110. The etch stop dielectric layer 110 comprises a dielectric material that is different from the dielectric material of the insulating matrix layer 40. For example, the etch stop dielectric layer 110 may comprise, and/or may consist essentially of, a dielectric metal oxide material such as aluminum oxide, a transition metal oxide, or an oxide of a Lanthanide metal. In this embodiment, the etch stop dielectric layer 110 may function as a stopping layer during formation of the channel cavities 23. A top surface of the etch stop dielectric layer 110 may be physically exposed at the bottom of each channel cavity 23. The bottom surface of the horizontally-extending portion of each U-shaped channel plate 20 contacts the top surface of the etch stop dielectric layer 110. Specifically, the bottom surface of the horizontally-extending portion of each U-shaped channel plate 20 may contact the top surface of the etch stop dielectric layer 110. A two-dimensional array of memory cells 99 may be formed.

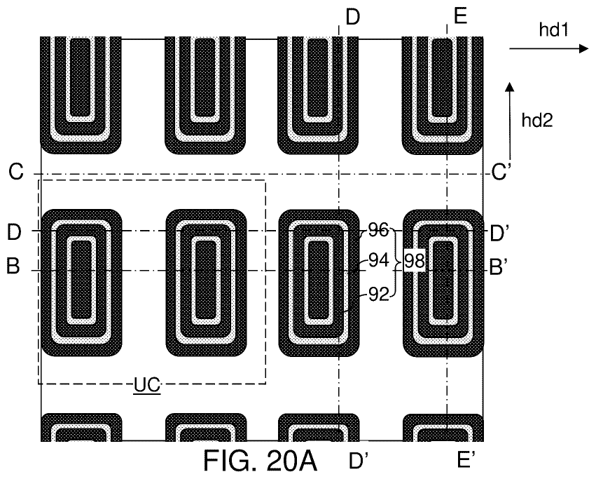

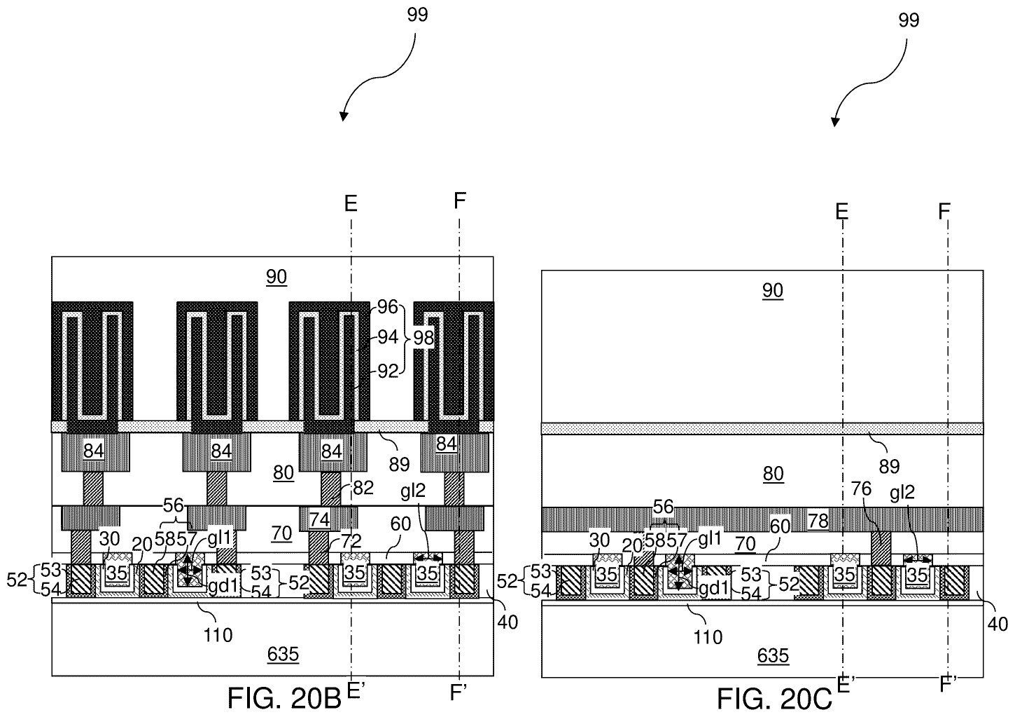

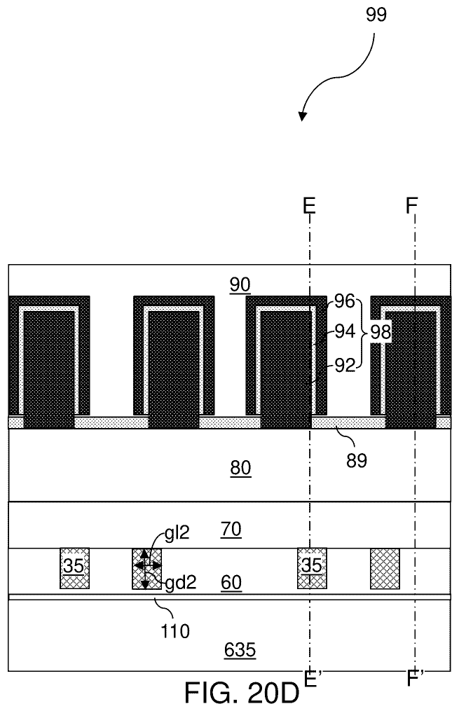

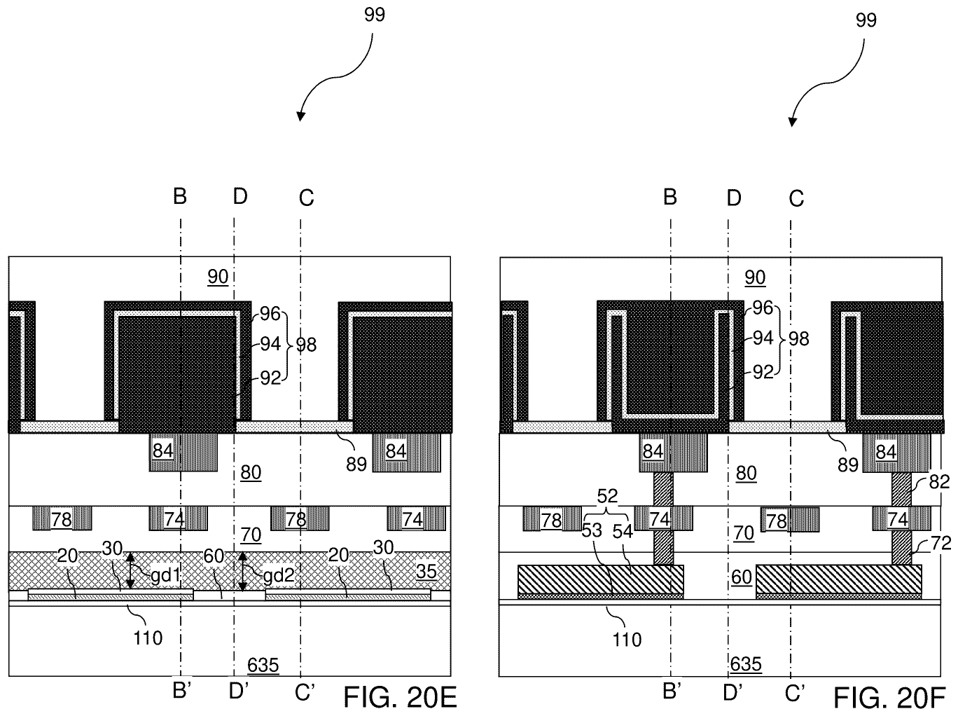

Referring to FIGS. 20A-20F, a first alternative embodiment of the third exemplary structure according to the third embodiment of the present disclosure may be derived from the third exemplary structure illustrated in FIGS. 19A-19F by reducing the thickness of the insulating matrix layer 40 such that the bottom surfaces of the source regions 52 and the drain regions 58 contact the etch stop dielectric layer 110. Further, the top surface of the etch stop dielectric layer 110 may be physically exposed at the bottom of each channel cavity 23. The bottom surface of the horizontally-extending portion of each U-shaped channel plate 20 may contact the top surface of the etch stop dielectric layer 110. In this embodiment, the bottom surface of the horizontally-extending portion of each U-shaped channel plate 20 may be located within the horizontal plane including the bottom surfaces of the source regions 52 and the drain regions 56.

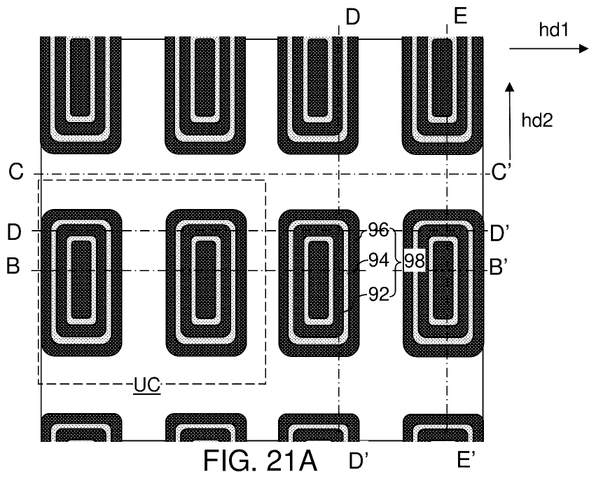

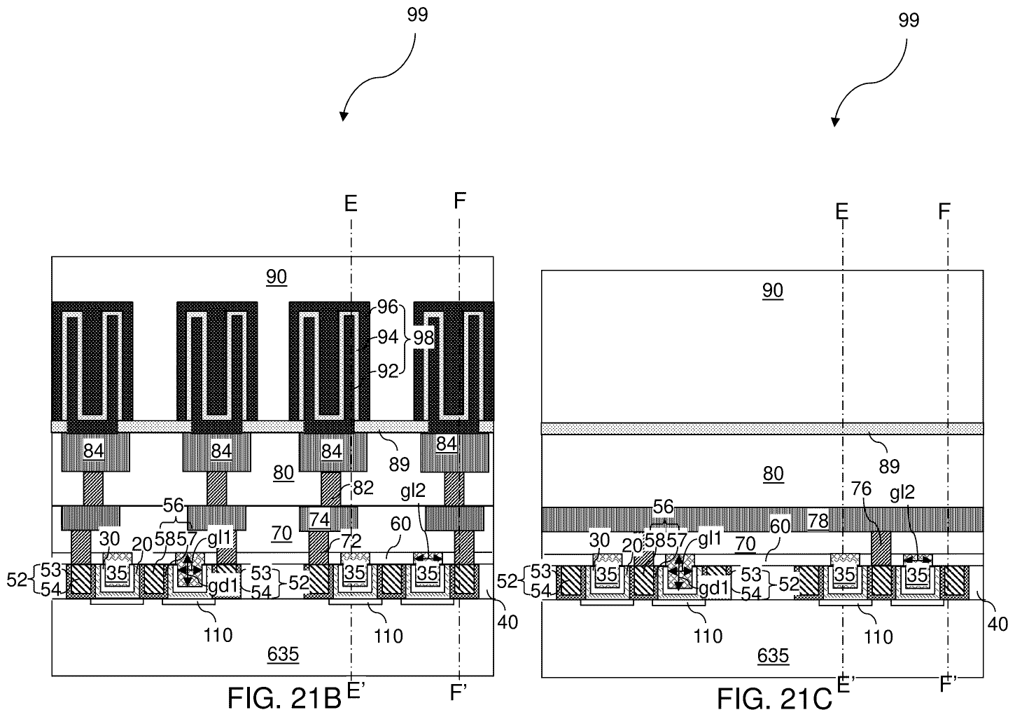

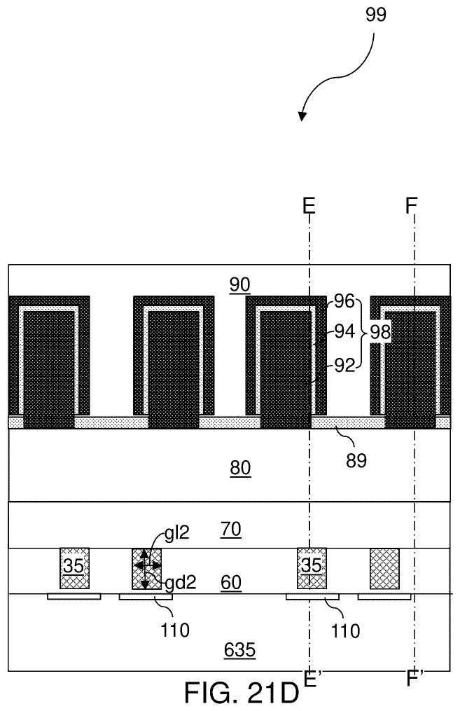

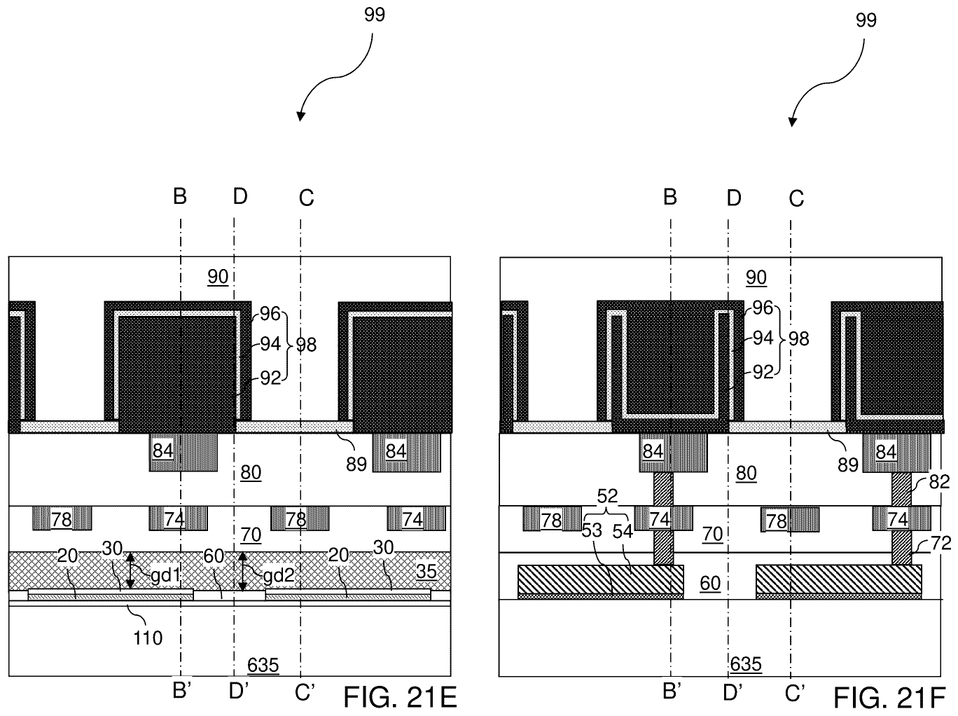

Referring to FIGS. 21A-21F, a second alternative embodiment of the third exemplary structure according to the third embodiment of the present disclosure may be derived from the third exemplary structure illustrated in FIGS. 19A-19F or from the first alternative embodiment of the third exemplary structure illustrated in FIGS. 20A-20F by forming the etch stop dielectric layer 110 as a plurality of etch stop dielectric material strips laterally extending along the second horizontal direction hd2 and laterally spaced among one another along the first horizontal direction hd1. In one embodiment, each strip of the etch stop dielectric layer 110 may have a greater area than the area of an overlying channel cavity 23 such that channel cavities 23 do not vertically extend below the horizontal plane including the top surfaces of the etch stop dielectric layer 110. The bottom surface of the horizontally-extending portion of each U-shaped channel plate 20 may contact the top surface of a respective strip of the etch stop dielectric layer 110. In this embodiment, the bottom surface of the horizontally-extending portion of each U-shaped channel plate 20 may be located within the horizontal plane including the bottom surfaces of the source regions 52 and the drain regions 56.

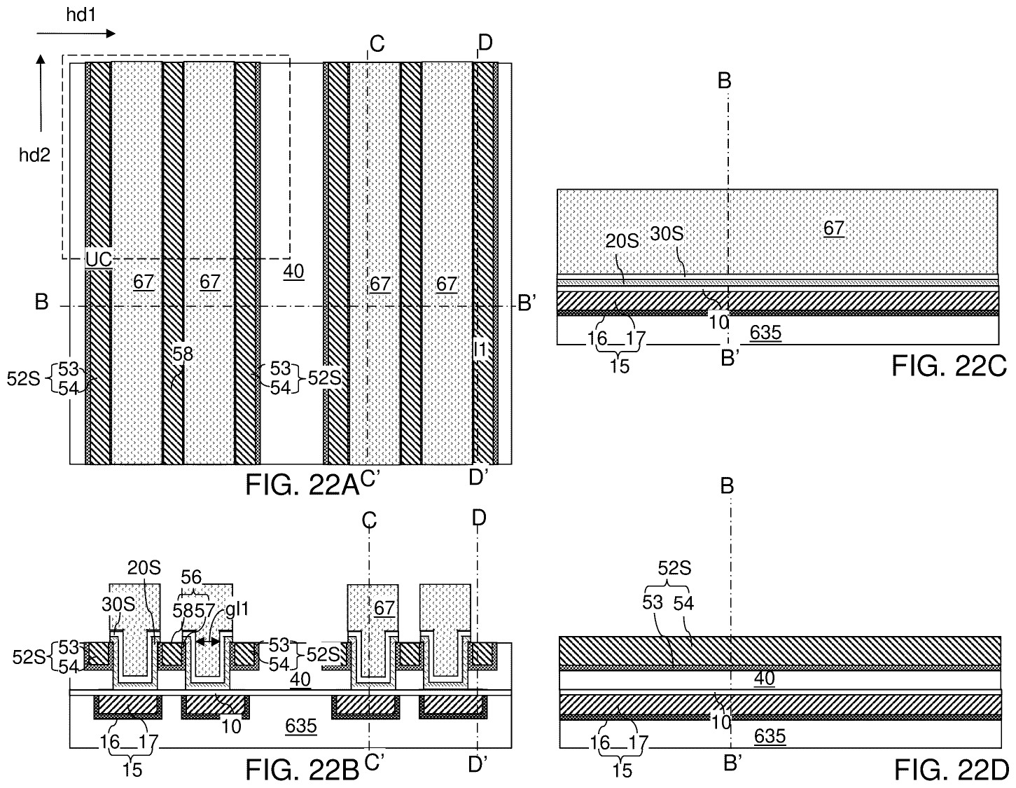

Referring to FIGS. 22A-22D, a fourth exemplary structure according to a fourth embodiment of the present disclosure may be derived from the first exemplary structure illustrated in FIGS. 7A-7D, or from equivalent structures of the second or third exemplary structure that corresponds to the first exemplary structure illustrated in FIGS. 7A-7D by patterning the gate dielectric layer 30L and the channel material layer 20L using a combination of lithographic methods and an etch process. Specifically, a photoresist layer 67 may be applied over the gate dielectric layer 30L, and may be lithographically patterned into line-shaped photoresist material portions covering the entire area of the channel cavities 23 as formed at the processing steps of FIGS. 6A-6D. In one embodiment, straight edges of the line-shaped photoresist material portions of the photoresist layer 67 may laterally extend along the second horizontal direction hd2, and may overlie a peripheral region of a respective neighboring pair of a source strip 52S and a drain strip 56S. The gate dielectric layer 30L and the channel material layer 20L may be patterned into gate dielectric strips 30S and the channel material strips 20S by performing an etch process (such as an anisotropic etch process) that etches unmasked portions of the gate dielectric layer 30L and the channel material layer 20L.

Each patterned portion of the gate dielectric layer 30L comprises a gate dielectric strip 30S. Each patterned portion of the channel material layer 20L comprises a channel material strip 20S. In embodiments in which an anisotropic etch process is used to remove unmasked portions of the gate dielectric layer 30L and the channel material layer 20L, sidewalls of the gate dielectric strips 30S may be vertically coincident with sidewalls of the channel material strips 20S. The photoresist layer 67 may be subsequently removed, for example, by ashing.

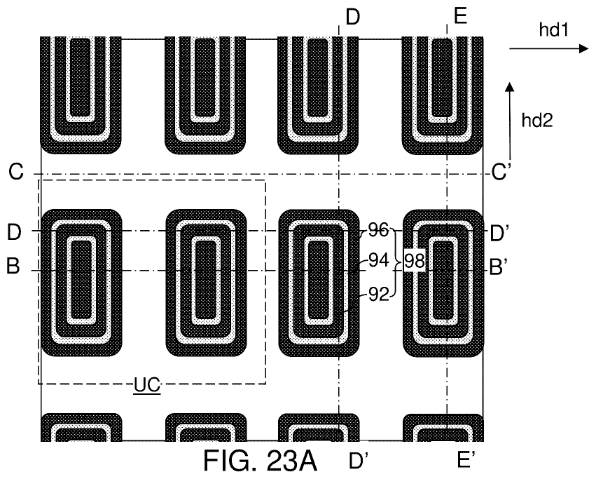

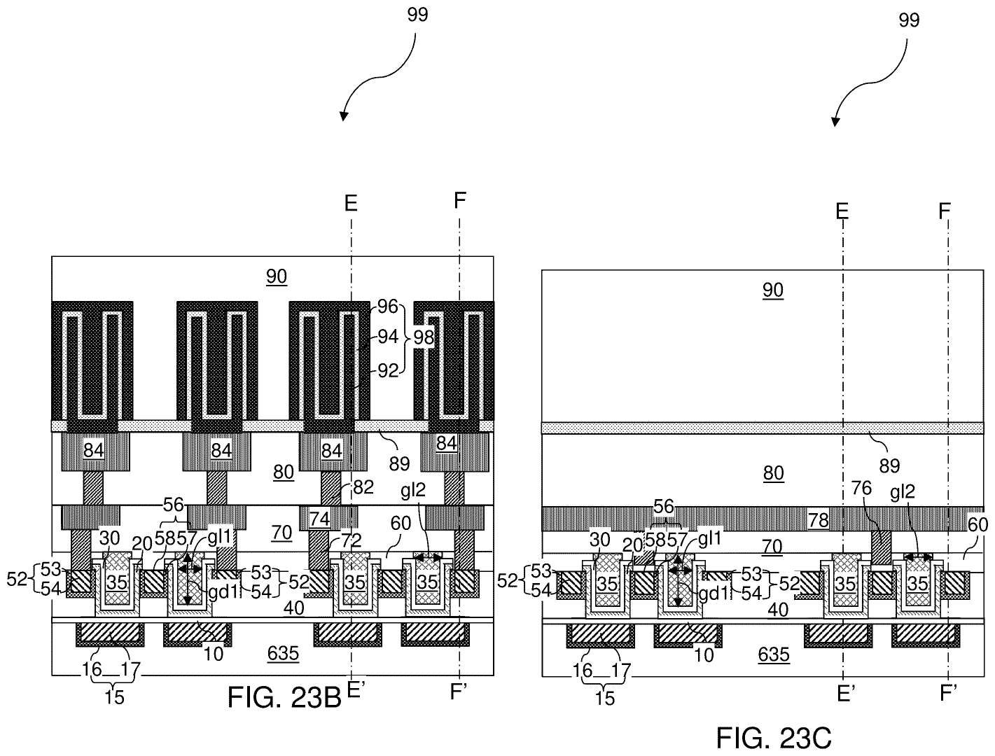

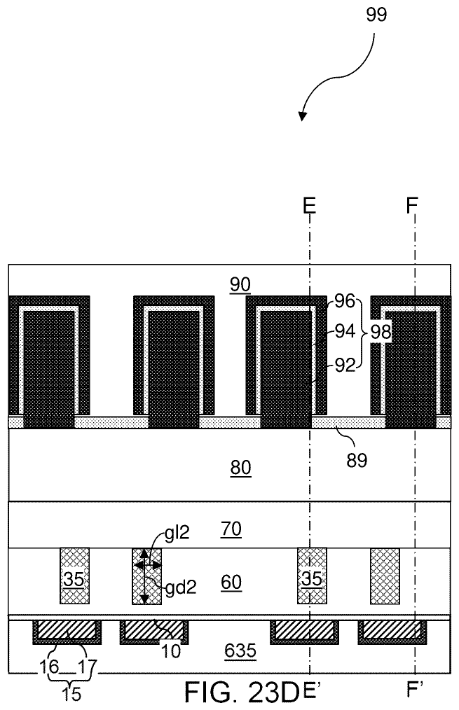

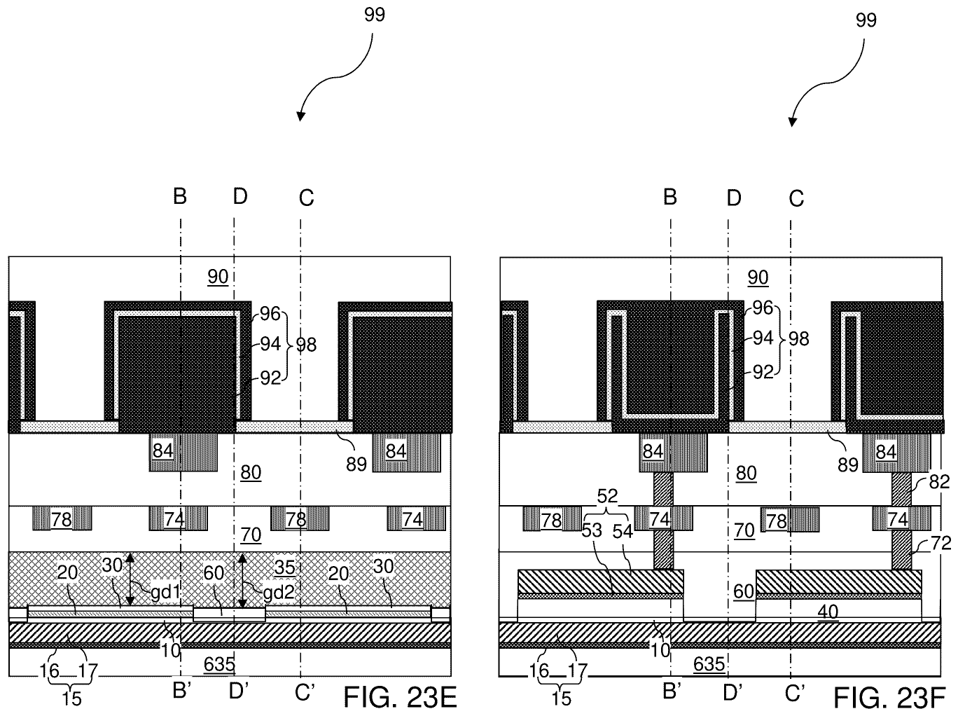

Referring to FIGS. 23A-23F, the processing steps of FIGS. 10A-10F, 11A-11F, 12A-12F, 13A-13F, 14A-14F, 15A-15F, and 16A-16F may be performed to form an array of transistors (e.g., TFTs), various metal interconnect structures, and an array of capacitor structures 98. A dynamic random access memory may be provided, which uses transistors including U-shaped channel plates 20. In this embodiment, the U-shaped gate dielectric 30 contacts an entirety of top surfaces of the U-shaped channel plate 20 within each transistor. The U-shaped gate dielectric 30 comprises horizontally-extending gate dielectric top portions that overlie peripheral portions of the source region 52 and the drain region 56 within each thin film transistor. A two-dimensional array of memory cells 99 may be formed.

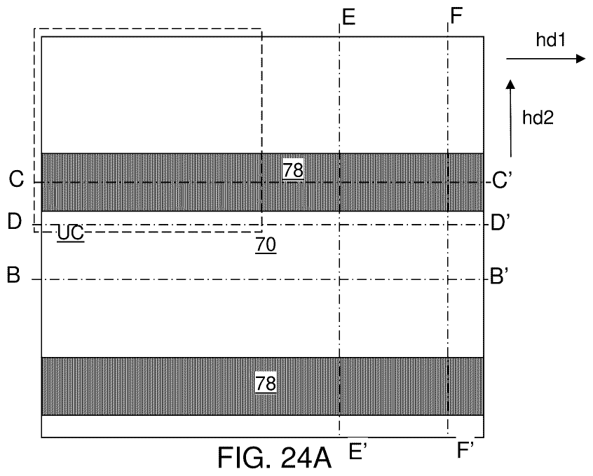

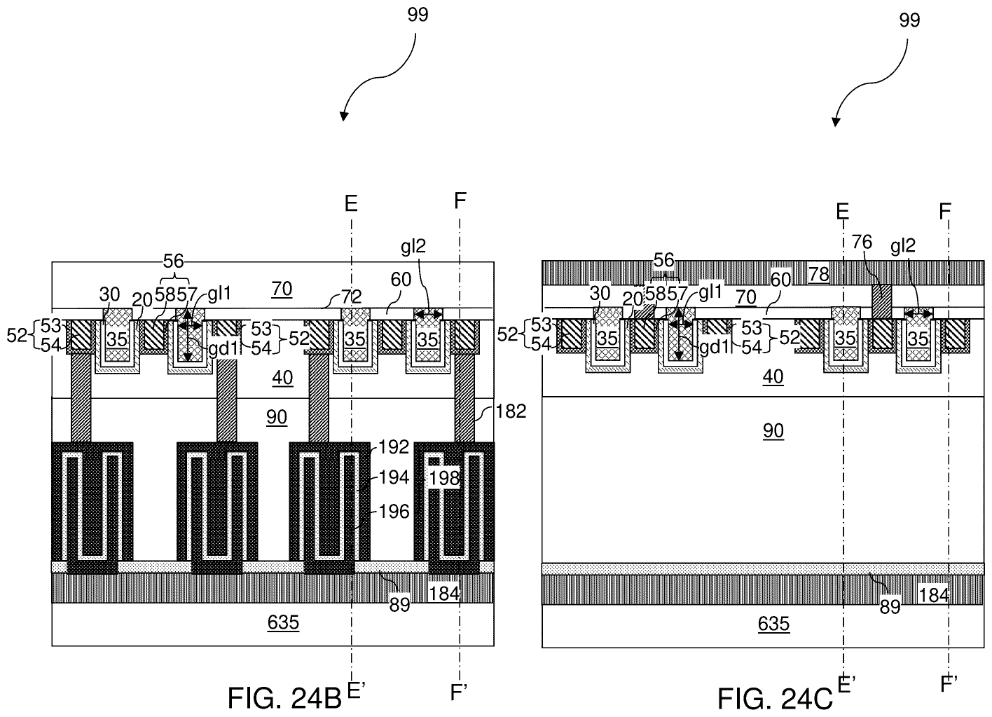

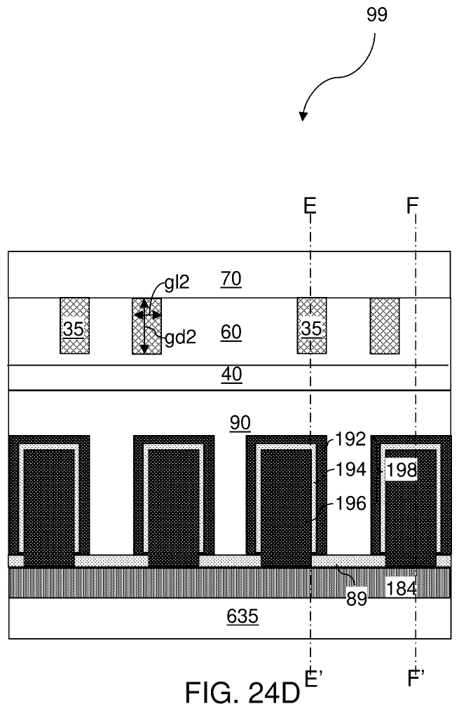

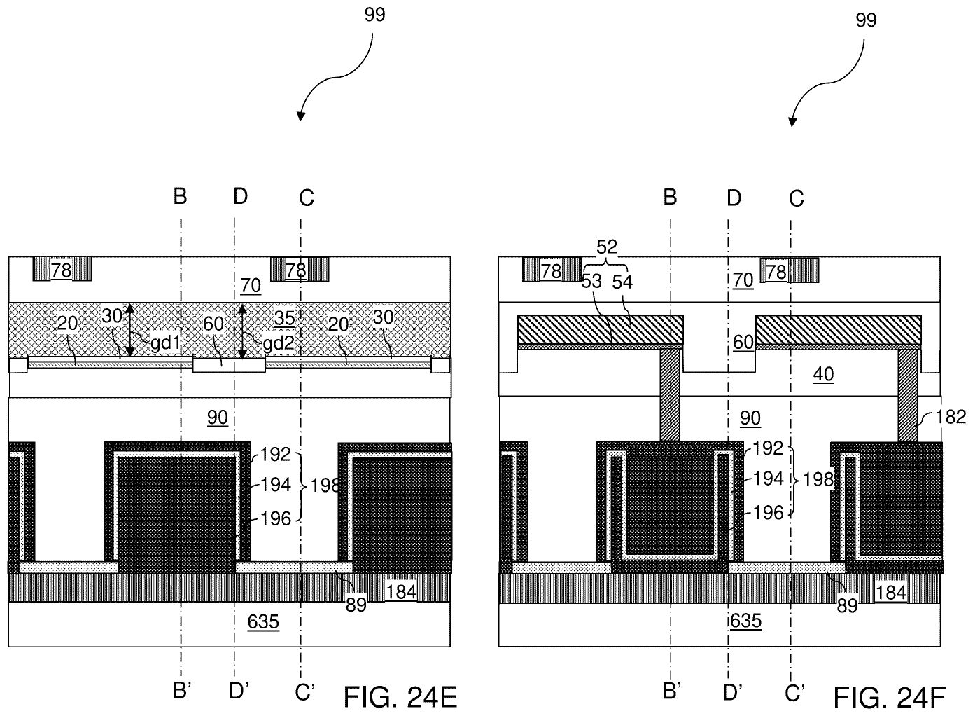

Referring to FIGS. 24A-24F, a fifth exemplary structure according to the fifth embodiment of the present disclosure may be derived from any of the first, second, third, or fourth exemplary structures of the present disclosure by forming an array of capacitor structures 198 prior to formation of the array of transistors (e.g., TFTs).

In an illustrative example, a conductive grounding plate 184 may be formed on a top surface of the insulating material layer 635 within the memory array region of the first exemplary structure as provided at the processing steps of FIG. 1. The conductive grounding plate 184 may comprise at least one metallic material such as at least one conductive metallic nitride material and/or at least one elemental metal. For example, the conductive grounding plate 184 may comprise tungsten or copper, and may have a thickness in a range from 20 nm to 400 nm, such as from 40 nm to 200 nm, although lesser and greater thicknesses may also be used.

Subsequently, the processing steps of FIGS. 16A-16F may be performed to form capacitor structures 198 and a capacitor-level dielectric material layer 90. For example, a dielectric etch stop layer 89 including a two-dimensional array of openings may be formed on the top surface of the conductive grounding plate 184. Second capacitor plates 196 may be formed on physically exposed portions of the top surface of the conductive grounding plate 184 by deposition and patterning a first conductive material, which may be a metallic material or a heavily doped semiconductor material. A node dielectric 194 may be formed on each second capacitor plate 196 by deposition of a node dielectric material such as silicon oxide and/or a dielectric metal oxide (e.g., aluminum oxide, lanthanum oxide, and/or hafnium oxide). A first capacitor plate 192 may be formed on physically exposed surfaces of the node dielectric 194 by deposition and pattering of a second conductive material, which may be a metallic material or a heavily doped semiconductor material.

Each contiguous combination of a first capacitor plate 192, a node dielectric 194, and a second capacitor plate 196 may constitute a capacitor structure 198. A pair of capacitor structures 198 may be formed within each unit cell UC. Thus, a first capacitor structure 198 and a second capacitor structure 198 may be formed within each unit cell UC. A capacitor-level dielectric material layer 90 may be formed over the capacitor structures 198. Each of the capacitor structures 198 may be formed within, and may be laterally surrounded by, the capacitor-level dielectric material layer 90.

An insulating matrix layer 40 may be formed over the top surface of the capacitor-level dielectric material layer 90. Capacitor contact via structures 182 contacting a top surface of a respective first capacitor plate 192 may be formed through the insulating matrix layer 40 and an upper portion of the capacitor-level dielectric material layer 90. The areas of the capacitor contact via structures 182 may be the same as the areas of the source contact via structures 72 in the first, second, third, and fourth exemplary structures.

In some embodiments, the source strips 52S, the drain strips 56S, and the capacitor contact via structures 182 may be formed by a dual damascene process in which combinations of a source trench 51 and a source contact via cavity that vertically extends downward from a bottom surface of the source trench 51 to a top surface of an underlying first capacitor plate 192 are formed concurrently with formation of the drain trenches 59, and are simultaneously filled with at least one conductive material. In this embodiment, the source regions 52, the drain regions 56, and the capacitor contact via structures 182 may comprise a same set of at least one metallic material.

Subsequently, the processing steps of FIGS. 6A-6D, 7A-7D, 8A-8D, 9A-9D, 10A-10F, 11A-11F, 12A-12F, and 13A-13F, or variations thereof, may be performed to form an array of transistors (e.g., TFTs). The processing steps of FIGS. 14A-14F may be performed with modifications so that source contact via structures 72 and the source connection pads 74 are not formed. A dynamic random access memory may be provided, which uses thin film transistors including U-shaped channel plates 20. A two-dimensional array of memory cells 99 may be formed.

In one embodiment, a first conductive node (such as a first capacitor plate 192) of a first capacitor structure 198 may be electrically connected to an overlying first source region 52, and a second conductive node (such as another first capacitor plate 192) of a second capacitor structure 198 may be electrically connected to an overlying second source region 52. In one embodiment, each of the first capacitor plates 192 may be electrically connected to (i.e., electrically shorted to) a respective one of the source regions 52. Each of the second capacitor plates 196 may be electrically connected to the conductive grounding plate 184, which may be electrically grounded.

Referring collectively to all previously described embodiments of the present disclosure, a two-dimensional array of capacitor structures (98, 198) may be formed prior to, or after, formation of a two-dimensional array of field effect transistors. In one embodiment, each of the capacitor structures (98, 198) comprises a first capacitor plate (92, 192) that is electrically connected to a source region 52 of a respective one of the field effect transistors within the two-dimensional array of field effect transistors, a node dielectric (94, 194), and a second capacitor plate (96, 196). In one embodiment, the two-dimensional array of field effect transistors may be arranged as a rectangular array extending along a first horizontal direction hd1 with a first pitch (i.e., with a first periodicity), and along a second horizontal direction hd2 with a second pitch (i.e., with a second periodicity). Each set of gate electrodes 35 arranged along the second horizontal direction hd2 may be merged as a respective gate electrode line that continuously extends along the second horizontal direction hd2. In one embodiment, the two-dimensional array of capacitor structures may be arranged as a rectangular array extending along the first horizontal direction hd1 with the first pitch (i.e., with the first periodicity), and along the second horizontal direction hd2 with the second pitch (i.e., with the second periodicity). In one embodiment, the first pitch may be the lateral dimension of a unit cell UC along the first horizontal direction hd1, and the second pitch may be the lateral dimension of the unit cell UC along the second horizontal direction hd2.

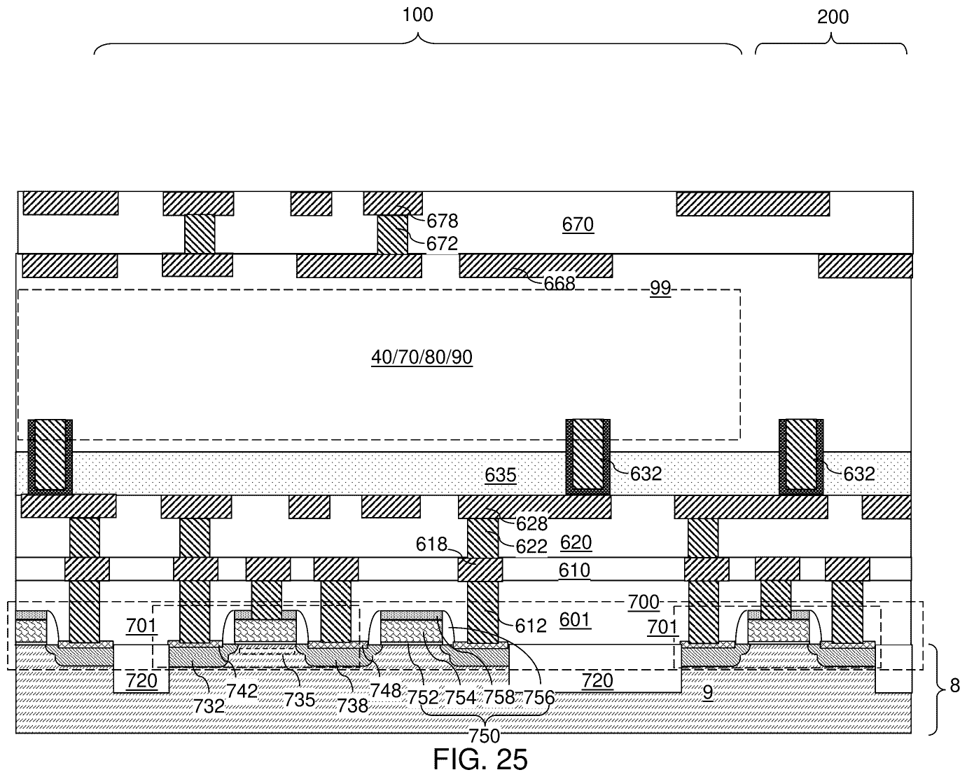

Referring to FIG. 25, an exemplary structure is illustrated after formation of a two-dimensional array of memory cells 99 over the insulating material layer 635. Various additional metal interconnect structures (632, 668) may be formed in the insulating material layer 635, the insulating matrix layer 40, and the upper-level dielectric material layers (70, 80, 90). The additional metal interconnect structures (632, 668) may include, for example, second metal via structures 632 that may be formed through the insulating material layer 635 and the Insulating matrix layer 40 on a top surface of a respective one of the second metal line structures 628. Further, the additional metal interconnect structures (632, 668) may include, for example, metal line structures that are formed in upper portions of the capacitor-level dielectric material layer 90, which are herein referred to as sixth metal line structures 668.

Additional interconnect-level dielectric material layer and additional metal interconnect structures may be subsequently formed. For example, a seventh interconnect-level dielectric material layer 670 embedding seventh metal line structures 678 and sixth metal via structures 672 may be formed above the capacitor-level dielectric material layer 90. While the present disclosure is described using an embodiment in which seven levels of metal line structures are used, embodiments are expressly contemplated herein in which a lesser or greater number of interconnect levels are used.

Generally, the field effect transistors 701 located on the substrate 8 may be electrically connected to the various nodes of the field effect transistors located within the insulating matrix layer 40. A subset of the field effect transistors 701 may be electrically connected to one or more nodes of the thin film transistors, which may comprise at least one of the drain regions 56, the bottom gate electrodes 15 (if present), the gate electrodes 35, and the source regions 52.

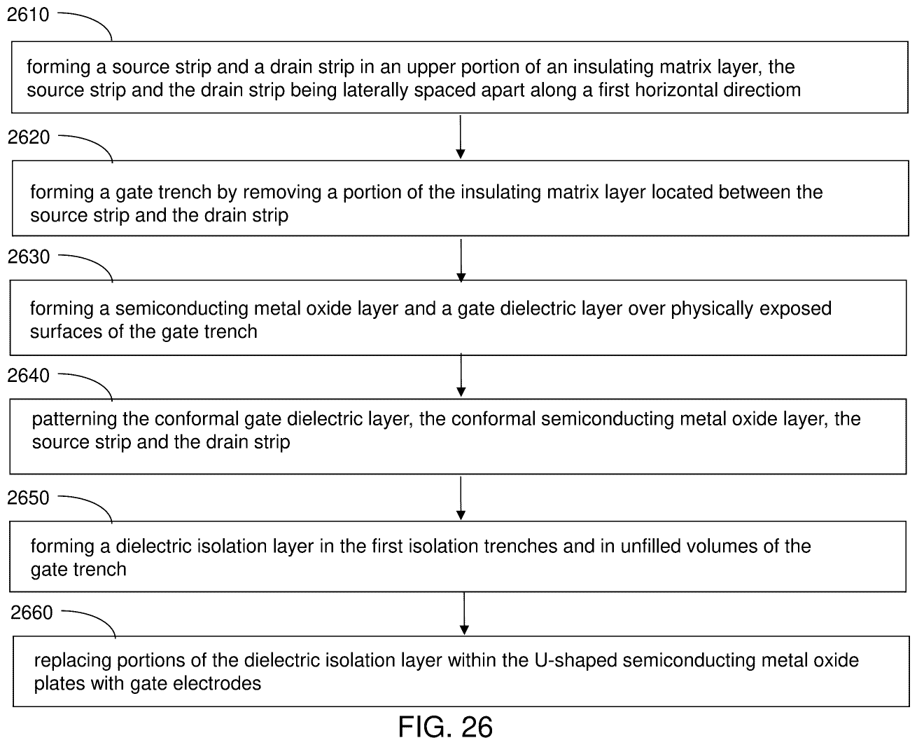

Referring to FIG. 26, a flowchart illustrates the general processing steps for manufacturing a semiconductor device of the present disclosure.

Referring to step 2610 and FIGS. 1-5D and FIGS. 17A-25 of the present disclosure, a source strip 52S and a drain strip 56S may be formed in an upper portion of an insulating matrix layer 40. The source strip 52S and the drain strip 56S may be laterally spaced apart along a first horizontal direction hd1.

Referring to step 2620 and FIGS. 6A-6D and FIGS. 17A-25, a channel cavity 23 may be formed by removing a portion of the insulating matrix layer 40 located between the source strip 52S and the drain strip 56S.

Referring to step 2630 and FIGS. 7A-7D and FIGS. 17A-25, a channel material layer 20L and a gate dielectric layer 30L may be formed over physically exposed surfaces of the channel cavity 23.

Referring to step 2640 and FIGS. 8A-8D, 9A-9D, and 10A-10F and FIGS. 17A-25, the gate dielectric layer 30L, the channel material layer 20L, the source strip 52S, and the drain strip 56S may be patterned by forming isolation trenches 29 laterally extending along the first horizontal direction hd1. A combination of a source region 52, a drain region 56, a U-shaped channel plate 20, and a U-shaped gate dielectric 30 may be formed between each neighboring pair of the isolation trenches 29.

Referring to step 2650 and FIGS. 11A-11F and FIGS. 17A-25, a dielectric isolation layer 60 may be formed in the isolation trenches 29 and in volumes of the channel cavity 23 that are not filled with the U-shaped channel plates 20 and the U-shaped gate dielectrics 30.

Referring to step 2660 and FIGS. 12A-25, at least first portions of the dielectric isolation layer 60 within the U-shaped channel plates 20 may be replaced with gate electrodes 35, thereby forming field effect transistors.

Referring to all drawings and according to various embodiments of the present disclosure, a semiconductor device comprising a field effect transistor is provided. The field effect transistor may include: a source region 52 and a drain region 56 located within an insulating matrix layer 40; a U-shaped channel plate 20 that includes a first vertically-extending portion contacting a sidewall of the source region 52, a second vertically-extending portion contacting a sidewall of the drain region 56, and a horizontally-extending portion connecting bottom ends of the first vertically-extending portion and the second vertically-extending portion and having a bottom surface located at, or below, a horizontal plane including bottom surfaces of the source region 52 and the drain region 56; a U-shaped gate dielectric 30 contacting inner sidewalls of the first vertically-extending portion and the second vertically-extending portion and contacting a top surface of the horizontally-extending portion; and a gate electrode 35 contacting inner sidewalls of the U-shaped gate dielectric 30 and a top surface of a horizontally-extending bottom portion of the U-shaped gate dielectric 30.

In one embodiment, a top surface of the U-shaped gate dielectric 30 may be located at, or below, or above, a horizontal plane including top surfaces of the source region 52 and the drain region 56. In one embodiment, top surfaces of the first vertically-extending portion and the second vertically-extending portion of the U-shaped channel plate 20 are located at, or below, or above, the horizontal plane including the top surfaces of the source region 52 and the drain region 56. In one embodiment, the semiconductor device may also include a dielectric isolation layer 60 overlying the source region 52 and the drain region 56, wherein a top surface of the gate electrode 35 may be located within a horizontal plane including a top surface of the dielectric isolation layer 60. In one embodiment, a top surface of the U-shaped gate dielectric 30 may be located below the horizontal plane including the top surface of the dielectric isolation layer 60. In one embodiment, the dielectric isolation layer 60 laterally surrounds the source region 52 and the drain region 56 and contacts sidewalls of the source region 52 and the drain region 56. In one embodiment, the source region 52 and the drain region 56 may be laterally spaced apart along a first horizontal direction hd1; a portion of the gate electrode 35 located between the first vertically-extending portion and the second vertically-extending portion has a first gate length along the first horizontal direction; and a portion of the gate electrode 35 laterally extending outside an area of the U-shaped gate dielectric 30 in a plan view has a second gate length along the first horizontal direction that is greater than the first gate length. In one embodiment, the portion of the gate electrode 35 located between the first vertically-extending portion and the second vertically-extending portion has a first gate depth along a vertical direction; and the portion of the gate electrode 35 laterally extending outside the area of the U-shaped gate dielectric 30 in the plan view has a second gate depth along the vertical direction that is greater than the first gate depth. In one embodiment, the bottom surface of the horizontally-extending portion of the U-shaped channel plate 20 may be located below the horizontal plane including the bottom surfaces of the source region 52 and the drain region 56 and contacts a top surface of a bottom gate dielectric layer 10 that overlies a bottom gate electrode 15. In one embodiment, the bottom surface of the horizontally-extending portion of the U-shaped channel plate 20 contacts a top surface of an etch stop dielectric layer 110. In one embodiment, the U-shaped gate dielectric 30 contacts an entirety of top surfaces of the U-shaped channel plate 20; and the U-shaped gate dielectric 30 may include horizontally-extending gate dielectric top portions that overlie peripheral portions of the source region 52 and the drain region 56. In one embodiment, the semiconductor structure may also include a first capacitor plate 92, a node dielectric 94, and a second capacitor plate 96, wherein the first capacitor plate 92 may be electrically connected to the source region 52.

According to another aspect of the present disclosure, a semiconductor device comprising a two-dimensional array of field effect transistors is provided. Each of the field effect transistors may include: a source region 52 and a drain region 56 located within an insulating matrix layer 40; a U-shaped channel plate 20 contacting sidewalls of the source region 52 and the drain region 56 and having a bottom surface located at, or below, a horizontal plane including bottom surfaces of the source region 52 and the drain region 56; a U-shaped gate dielectric 30 contacting inner sidewalls of the U-shaped channel plate 20; and a gate electrode 35 contacting inner sidewalls of the U-shaped gate dielectric 30. The field effect transistors are laterally spaced among one another by a dielectric isolation layer 60 overlying each of the source regions 52 and the drain regions 56 and contacting sidewalls of each of the source regions 52 and the drain regions 56.

In one embodiment, the two-dimensional array of field effect transistors may be arranged as a rectangular array extending along a first horizontal direction and along a second horizontal direction; each set of gate electrodes 35 arranged along the second horizontal direction may be merged as a respective gate electrode line that continuously extends along the second horizontal direction. In one embodiment, the semiconductor device may also include a two-dimensional array of capacitor structures 198, wherein each of the capacitor structures 198 comprises a first capacitor plate 92, 192 that may be electrically connected to a source region 52 of a respective one of the field effect transistors within the two-dimensional array of field effect transistors, a node dielectric 94, and a second capacitor plate 96.

The various embodiments of the present disclosure may provide transistors (e.g., TFTs) in which a U-shaped channel plate 20, a U-shaped gate dielectric 30, and a gate electrode 35 are self-aligned to a neighboring pair of a source region 52 and a drain region 56. The vertical dimensions of the vertically-extending portions of the U-shaped channel plate 20 may be adjusted to control the effective channel length between the source region 52 and the drain region 56, i.e., the actual distance that charge carriers need to travel from the source region 52 to the drain region 56. In one embodiment, the effective channel length may be greater than the lateral spacing between the source region 52 and the drain region 56. Device variability associated with misalignment of a gate electrode from the source region and/or the drain region may be eliminated in the transistors of the present disclosure due to the self-alignment of the U-shaped channel plate 20, the U-shaped gate dielectric 30, and the gate electrode 35 to the combination of the source region 52 and the drain region 56. The transistors of the present disclosure may be used in an array environment as access transistors such as access transistors for a memory array.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor device, comprising:
forming a source strip and a drain strip in an upper portion of an insulating matrix layer, the source strip and the drain strip being laterally spaced apart along a first horizontal direction;
removing a portion of the insulating matrix layer located between the source strip and the drain strip to form a channel cavity;
depositing a channel material layer and a gate dielectric layer over physically exposed surfaces of the channel cavity;
patterning the gate dielectric layer, the channel material layer, the source strip and the drain strip by forming isolation trenches laterally extending along the first horizontal direction, wherein a combination of a source region, a drain region, a U-shaped channel plate, and a U-shaped gate dielectric is formed between each neighboring pair of the isolation trenches;
depositing a dielectric isolation layer in the isolation trenches and in volumes of the channel cavity that are not filled with the U-shaped channel plates and the U-shaped gate dielectrics; and
replacing at least first portions of the dielectric isolation layer within the U-shaped channel plates with gate electrodes, whereby field effect transistors are formed.

2. The method of claim 1, further comprising:
forming a gate cavity by removing the first portions of the dielectric isolation layer and second portions of the dielectric isolation layer located between neighboring pairs of the first portions of the dielectric isolation layer; and
depositing a gate electrode material within the gate cavity, whereby a gate electrode line including the gate electrodes is formed.

3. The method of claim 2, wherein:
the channel material layer is deposited by a first conformal deposition process;
the gate dielectric layer is deposited by a second conformal deposition process; and
the dielectric isolation layer is formed with a planar horizontal surface.

4. The method of claim 3, wherein the gate cavity is formed by applying and patterning a photoresist layer such that the first portions of the dielectric isolation layer and the second portions of the dielectric isolation layer are not masked by the photoresist layer, and by etching unmasked portions of the dielectric isolation layer selective to a material of the gate dielectric layer.

5. The method of claim 1, further comprising:
forming an etch mask material portion over the gate dielectric layer, wherein the etch mask material portion fills volumes of the channel cavity that remain unfilled after formation of the gate dielectric layer; and
removing portions of the gate dielectric layer and the channel material layer using the etch mask material portion as an etch mask, whereby top surfaces of the source strip and the drain strip are physically exposed.

6. The method of claim 1, further comprising forming capacitor structures prior to, or after, formation of the field effect transistors, wherein each of the capacitor structures comprises a first capacitor plate that is electrically connected to a source region of a respective one of the field effect transistors, a node dielectric, and a second capacitor plate.

7. A method of forming a semiconductor device, comprising:
forming a bottom gate electrode in an insulating layer;
depositing a bottom gate dielectric layer and an insulating matrix layer over the bottom gate electrode;
forming a source region and a drain region within the insulating matrix layer such that top surfaces of the source region and the drain region are coplanar with a top surface of the insulating matrix layer;
etching a channel cavity in the insulating matrix layer between the source region and the drain region;
forming a combination of a U-shaped channel plate and a U-shaped gate dielectric in the channel cavity; and
forming a top gate electrode on the U-shaped gate dielectric.

8. The method of claim 7, further comprising:
etching a source cavity and a drain cavity in the insulating matrix layer; and
depositing at least one metallic material in the source cavity and the drain cavity; and
performing a planarization process that removes portions of the at least one metallic material from above the source cavity and the drain cavity, wherein remaining portions of the at least one metallic material comprise the source region and the drain region.

9. The method of claim 8, wherein the at least one metallic material comprises a metallic liner material and a metallic fill material.

10. The method of claim 7, further comprising forming a patterned photoresist layer over the source region and the drain region, wherein the channel cavity is formed in a region that is not masked by the patterned photoresist layer, the source region, or the drain region.

11. The method of claim 7, further comprising:
depositing a channel material layer on the source region and the drain region;
depositing a top gate dielectric layer over the channel material layer; and
patterning the top gate dielectric layer and the channel material layer, wherein patterned portions of the top gate dielectric layer and the channel material layer comprise the U-shaped gate dielectric and the U-shaped channel plate.

12. The method of claim 11, further comprising:
applying an etch mask material within unfilled volumes of the channel cavity after deposition of the gate dielectric layer;
removing excess portions of the etch mask material from above a horizontal plane including a top surface of the gate dielectric layer; and
removing portions of the gate dielectric layer and the channel material layer that are not masked by the etch mask material.

13. The method of claim 11, further comprising:
applying a photoresist layer over the gate dielectric layer;
patterning the photoresist layer to cover an area of the channel cavity without covering distal portions of the source region and the drain region; and
removing portions of the gate dielectric layer and the channel material layer that are not masked by the patterned photoresist layer.

14. The method of claim 7, further comprising:
depositing a dielectric isolation layer over the U-shaped gate dielectric; and
etching a gate cavity through the dielectric isolation layer such that the gate cavity comprises a fraction of a volume of the channel cavity, wherein the top gate electrode is formed in the gate cavity.

15. A method of forming a semiconductor device, comprising:
forming a bottom gate electrode in an insulating layer;
depositing a bottom gate dielectric layer and an insulating matrix layer over the bottom gate electrode;
etching a source cavity and a drain cavity in the insulating matrix layer such depths of the source cavity and the drain cavity are less than a thickness of the insulating matrix layer;
forming a source region and a drain region within the insulating matrix layer;
etching a channel cavity in the insulating matrix layer between the source region and the drain region;
forming a combination of a U-shaped channel plate and a U-shaped gate dielectric in the channel cavity;
forming a top gate electrode on the U-shaped gate dielectric.

16. The method of claim 15, further comprising:
depositing at least one metallic material in the source cavity and the drain cavity; and
performing a planarization process that removes portions of the at least one metallic material from above a horizontal plane including a top surface of the insulating matrix layer, wherein remaining portions of the at least one metallic material comprise the source region and the drain region.

17. The method of claim 15, wherein the channel cavity is formed by performing an anisotropic etch process that employs a combination of a patterned photoresist layer, the source region, and the drain region as an etch mask, and wherein segments of top surfaces of the source region and the drain region are exposed during removal of material portions of the insulating matrix layer while performing the anisotropic etch process.

18. The method of claim 15, wherein a segment of a top surface of the bottom gate dielectric layer is physically exposed at a bottom of the channel cavity upon formation of the channel cavity.

19. The method of claim 15, wherein the channel cavity is laterally bounded by a sidewall of the source region, a sidewall of a drain region, a first sidewall of the insulating matrix layer that connects the sidewall of the source region to a top surface of the bottom gate dielectric layer, and a second sidewalls of the insulating matrix layer that connects the sidewall of the drain region to the top surface of the bottom gate dielectric layer.

20. The method of claim 15, wherein a top surface of a horizontally-extending portion of the U-shaped channel plate is formed below a horizontal plane including bottom surfaces of the source region and the drain region.
